(19) United States
(12) Patent Application Publication
(10) Pub. No.: US 2010/0164870 A1
(43) Pub. Date: Jul. 1, 2010

(54) KEY SHEET

(76) Inventors: Tedi Kunthady, Tokyo (JP); Masami Arai, Tokyo (JP); Kengo Nishi, Tokyo (JP); Yutaka Takezawa, Fukushima (JP); Atsushi Hikita, Tokyo (JP)

Correspondence Address: Tomoko Nakajima;Cermak Nakajima LLP, 127 S. Peyton Street, Suite 210, Alexandria, VA, 22314, US

(21) Appl. No.: 12/668,898

(22) PCT Filed: Jul. 11, 2008
(86) PCT No.: PCT/JP2008/062549

§ 371 Date: Feb. 25, 2010

(30) Foreign Application Priority Data
Jul. 13, 2007 (JP) 2007-184416
May 29, 2008 (JP) 2008-140396
Jun. 30, 2008 (JP) 2008-169946
Jul. 3, 2008 (JP) 2008-174431

(51) Int. Cl. G06F 3/02; H03M 11/00

(52) U.S. Cl. 345/168; 341/22

(57) ABSTRACT

Provided is a key sheet which has a soft touch feeling and in which elaborate and highly visible display portions can be provided. In a key sheet including: a translucent base sheet; and a soft-feel layer which is laminated on a front surface side of the base sheet, includes a plurality of display portions representing key types such as letters, numerals, and symbols, and has a soft touch feeling, the soft-feel layer includes a translucent skin layer having the soft touch feeling and decorative portions which are provided on a back surface of the skin layer and are visible through the skin layer. Further, light emitted from an inside of a device transmits through the base sheet so as to reach the decorative portions, and hence it is possible to obtain an illumination-type key sheet excellent in illumination property and of wider variety.

### TECHNICAL FIELD

The present invention relates to a key sheet which is used for operating parts of various electronic devices such as handheld information terminals, PDAs, AV devices, various remote controllers, and various keyboards, and which provides a soft touch feeling when fingers of an operator come into touch therewith at the time of an input operation.

### BACKGROUND ART

Electronic devices such as handheld information terminals and PDAs have been downsized and reduced in thickness. In accordance therewith, a key sheet used for the electronic devices has been demanded to be downsized and reduced in thickness. As a key sheet meeting the demand, there has been known a thin key sheet provided with an operating plate made of a metal, a hard resin, or the like (Patent Document 1).

Meanwhile, decoration for providing a key sheet with a leather-like expensive appearance, and a soft touch feeling at the time of an operation has been considered for the purpose of differentiation by adding a value in terms of design. As a decorative member used therefor, there have been known a decorative sheet obtained by laminating synthetic leather on a front surface of a resin-molded product, and a decorative sheet obtained by laminating a skin-layer resin film and a foam sheet on each other (Patent Documents 2 and 3).
Patent Document 1: JP 2006-156333 A
Patent Document 2: JP 2003-71956 A
Patent Document 3: JP 2004-216880 A

### DISCLOSURE OF THE INVENTION

### Problems to be solved by the Invention

As described above, in order to realize the key sheet which meets the demand for downsizing and reduction in thickness of the electronic devices while providing a leather-like expensive appearance, and a soft touch feeling at the time of a pressing operation, the decorative sheets described in Patent Documents 2 and 3 may be converted to the key sheet. However, the decorative sheet described in Patent Document 2 is provided with clipped portions representing patterns of display elements such as letters and symbols, and cutout surfaces of the clipped portions are exposed as they are. Thus, when being used, the decorative sheet described in Patent Document 2 may be abraded or rolled-up from the cutout surfaces of the clipped portions through repeated pressing operations.

Under the circumstance, as an invention for overcoming the disadvantage as described above, the applicants of the present invention devised a decorative sheet which provides a leather-like appearance and a soft touch feeling and is excellent in durability. The decorative sheet includes a soft-feel layer having a two-layer structure of a skin layer and a foam layer, the skin layer realizing a leather-like appearance and the combination of the skin layer and the foam layer realizing a soft touch feeling. In terms of the above-mentioned durability, edge portions of the foam layer are structured in a wrapped/hidden manner with the skin layer so as not to be exposed as they are. In this manner, abrasion and rolling-up are prevented. However, in the decorative sheet, display elements representing key types such as letters, numerals, and symbols are three-dimensionally formed by depressing the soft-feel layer. Thus, there is a problem of difficulty in forming elaborate display elements such as fine letters and complicated symbols.

In order to solve this problem, the inventors of the present invention considered providing the elaborate display elements by printing. However, when the display elements are directly printed on the front surface of the soft-feel layer (skin layer), the skin layer is covered with a printed layer. Thus, there arises problems of impairing an original soft touch feeling and peeling off of the printed display elements. Further, when the display elements are printed on the back surface of the soft-feel layer (foam, layer), the display elements have to be viewed through thicknesses of the skin layer and the foam layer. Thus, there arises a problem of deteriorating visibility.

When a key sheet is illuminated with an inner light source of an electronic device (backlight illumination), in a case of using the decorative sheet described in Patent Document 2, the clipped portions representing display elements such as letters and symbols may be used as illumination portions. Meanwhile, as described above, the cutout surfaces of the clipped portions are exposed as they are. Thus, the decorative sheet may be abraded or rolled-up from the cutout surfaces of the clipped portions through repeated pressing operations. Further, the decorative sheet described in Patent Document 3, in which the foam sheet is laminated on the back surface of the skin-layer resin film for the purpose of providing a soft touch feeling, has a problem of weakening brightness as a result of light scattered through the foam sheet.

In addition, while a key sheet with a gentle touch feeling can be realized by the soft-feel layer, there has been a demand for a key sheet which is more visually interesting and has high value in terms of design of an outward appearance.

The present invention has been made under the above-mentioned circumstances. That is, it is an object of the present invention to provide a key sheet which has a soft touch feeling and in which elaborate and highly visible display elements can be provided. It is another object of the present invention to provide a key sheet excellent in durability. It is still another object of the present invention to provide a key sheet exhibiting excellent visibility even in a case of being used as a so-called illumination-type key sheet such as a key sheet which is used for mobile phones is illuminated with backlight. It is yet another object of the present invention to provide a key sheet with an outward appearance which is three-dimensionally and gradually changed in hue. It is yet another object of the present invention to provide a key sheet with a brand-new design in which display elements can be switched between an illumination state and a non-illumination state with backlight.

### Means for solving the Problems

In order to achieve the above-mentioned object, the present invention provides a key sheet including: a base sheet; and a soft-feel layer laminated on a front surface side of the base sheet and having a soft touch feeling, in which the soft-feel layer includes: a translucent skin layer having the soft touch feeling; and decorative portions visible through the skin layer.

In the key sheet including the base sheet and the soft-feel layer laminated on the front surface side of the base sheet and having the soft touch feeling, the skin layer of the soft-feel layer is translucent, and hence it is possible to enhance visibility of the decorative portions visible through the skin layer. Further, by an asperity pattern on an operating surface or depending on a quality of a resin material for the skin layer, the skin layer having the soft touch feeling may be provided as a layer with a leather-like touch feeling.

In addition, the key sheet of the present invention may be described while being divided into four types in all of which those components are commonly provided and in each of which other components are individually provided.

In a key sheet of a first type of the present invention, the base sheet is translucent, and the decorative portions of the soft-feel layer includes a character layer provided on a back surface of the skin layer and having a printed layer in which a plurality of display elements representing key types including letters, numerals, and symbols are formed. With this, the display elements can be easily formed by printing on the back surface of the skin layer, and in addition, the display elements thus obtained are visible through the translucent skin layer. In this manner, it is possible to obtain display elements excellent in visibility.

Further, the soft-feel layer is laminated on the front surface side of the translucent base sheet, and hence light emitted from an inside of a device transmits through the base sheet so as to reach the character layer having the printed layer in which the display elements are formed. Thus, it is possible to obtain an illumination-type key sheet excellent in illumination property and of wider variety. Note that, the character layer may include “display portions” constituting the display elements representing key types such as letters, numerals, and symbols and “background portions” forming peripheries of the display portions. Alternatively, in addition to the display portions and the background portions, the character layer may include a “frame portion” which is a portion except pressing-operation parts constituted by the display portions and the background portions and corresponds to a frame; or “partition portions” for partitioning the pressing-operation parts. In any cases, the character layer may be constituted at least by the display portions, the background portions, or the printed layer.

In the invention of the prior application filed by the applicants of the subject application, the soft-feel layer is constituted by the combination of the skin layer providing a leather-like touch feeling and the foam layer providing a soft bulge-like feeling. Thus, it is difficult to form display elements on any of the front and back surfaces thereof. In contrast, in the present invention, display elements are provided on the back surface of the translucent skin layer. Thus, it is possible to easily form display elements excellent in visibility, and the display elements thus obtained are excellent in durability. In addition, the present invention adopts a structure free from the foam layer unlike the invention of the prior application. Thus, it is possible to prevent deterioration of illumination properties owing to transmittance of light through the foam layer, and hence possible to provide a key sheet excellent in illumination property.

That is, in the present invention, the soft-feel layer is provided on the operating surface, and hence it is possible to provide a leather-like soft touch feeling at a time of performing an input operation, and it is possible to make the key sheet look like a leather. Further, the display elements are provided on the back surface of the translucent skin layer, and hence it is possible to enhance visibility of the display elements while preventing abrasion of the display elements. In addition, it is possible to easily form the display elements by printing or the like, and hence possible to easily form fine display elements.

Further, the base sheet and the skin layer are translucent, and hence it is possible to perform illumination through the character layer when the character layer is translucent. Thus, according to the present invention, it is possible to realize a key sheet which has display elements excellent in soft touch feeling and durability and which can be illuminated. Note that, a leather-like touch feeling of the soft-feel layer of the present invention may be provided by an asperity pattern on the operating surface or depending on a quality of a resin material for the skin layer.

In the key sheet of the first type, the soft-feel layer may include through-holes as partition lines for partitioning the display elements. With provision of the through-holes as the partition lines for partitioning the display elements with respect to the soft-feel layer, light emitted from the inner light source transmits through the translucent base sheet so as to be emitted through the through-holes to the outside. Thus, it is possible to differentiate a degree of illumination from the display elements and a degree of illumination from the partition lines from each other. As a result, it is possible to provide a key sheet with characteristic illumination properties. Further, even when the character layer is not translucent, at least the display elements can be distinguished from each other with the illumination from the partition lines. Note that, herein, the “partition lines” for partitioning the display elements may partition one of the display elements from the other display elements like partition lines for partitioning display elements adjacent to each other, or may partition one of the pressing-operation parts constituted by background portions and display portions forming display elements from the other parts of the pressing-operation parts and portions other than the pressing-operation parts.

When the partition lines are provided as described above, it is possible to cause the input operation parts to be more visible and possible to prevent misinputs. Note that, both the display portions forming display elements and the portions other than the display portions may be translucent, or any one of them may be lightproof. That is, the display portions are visible when light transmittance of the display portions and light transmittance of the portions other than the display portions are different from each other. Further, when color tones therebetween are different from each other even with substantially the same light transmittance, the display portions are visible. The shape of the partition lines is a shape allowing substantial definition of the input operation parts. For example, there may be provided a shape of surrounding outer peripheries of the input operation parts in a frame-like manner, a shape of forming a part of the outer peripheries of the input operation parts, and the like. In this context, the through-holes are provided as the partition lines for defining the input operation parts, and hence the partition lines can be brightly illuminated. Further, the input operation parts can be confirmed also with touch feelings owing to the partition lines. In addition, at the time of performing a pressing operation, the key sheet is easily deflected, and hence pressing load can be suppressed. As a result, it is possible to enhance pressing operability.

Further, in the key sheet of the first type, the soft-feel layer may further include a porous layer on a back surface side of the character layer. The soft-feel layer further includes the porous layer on the back surface side of the character layer. Thus, the operating surface of the soft-feel layer can be depressed more easily owing to flexibility of the porous layer. As a result, it is possible to further increase a soft touch feeling. Even with the provision of the porous layer as described above, display elements are formed on an upper surface of the porous layer. Thus, the display elements are visible without interference of the porous layer, and hence visibility is not impaired.

In the key sheet of the first type including the porous layer, the skin layer of the soft-feel layer may include a protective portion for covering a side surface of an edge portion of the porous layer. With the provision of the protective portion for covering the side surface of the edge portion of the porous layer with respect to the skin layer of the soft-feel layer, the porous layer is not exposed to the outside, and hence it is possible to enhance durability of the porous layer.

Further, regarding the through-holes provided as partition lines in the soft-feel layer, in order that side surfaces of the porous layer are not exposed from the through-holes, the skin layer may extend so as to form protective portions for covering the side surfaces. As a result, exposed portions of the porous layer are eliminated not only on the side surface of the key sheet but also in portions corresponding to the through-holes, and hence it is possible to provide a key sheet of higher rigidity.

Similarly to the invention of the prior application, a foam layer may be used as the porous layer. In this context, when illumination through the porous layer is performed, it is preferred that a porous layer of higher translucency be provided.

The present invention provides a key sheet of the second type, in which the decorative portions of the soft-feel layer are provided on a back surface side of the skin layer and constitute display elements including letters, numerals, and symbols, and the soft-feel layer further includes a hair-implanted layer which is provided on the back surface side of the skin layer and in which piles are implanted in a direction crossing a plane direction of the base sheet. With this, the display elements are provided on the back surface side of the skin layer, and hence it is possible to enhance visibility of the display elements. Further, with the provision of the hair-implanted layer in which the piles are implanted in the direction crossing the plane direction of the base sheet, a soft touch feeling is provided owing to flexibility of the hair-implanted layer. Thus, synergistically with a touch feeling of the skin layer, it is possible to realize a key sheet with a more excellent leather-like touch feeling.

The hair-implanted layer in which the piles are implanted is compressed in a thickness direction owing to deflection of the piles when the skin layer is pressed. When the skin layer is released from a pressing state, the piles thus deflected are restored to the original shape and a thickness of the skin layer is restored. Thus, when the skin layer is brought into touch, the front surface thereof is slightly depressed and a soft touch feeling is provided. As a result, it is possible to realize a key sheet with a leather-like soft touch feeling. Note that, the leather-like soft touch feeling of the soft-feel layer of the present invention may be provided by an asperity pattern on the operating surface or depending on a quality of a resin material for the skin layer.

Further, in the hair-implanted layer, light transmits between the piles implanted in the direction crossing the plane direction of the base sheet. Thus, the light transmitting through the hair-implanted layer is less liable to be scattered, and hence light transmittance thereof is excellent. Therefore, the key sheet constituted by the translucent base sheet, the translucent hair-implanted layer, and the translucent skin layer allows illumination with backlight. As a result, it is possible to realize a key sheet excellent in visibility of display elements even in a dark place.

In addition, the piles are stiff owing to natural fiber or artificial fiber used as a raw material therefor, and hence durability of the key sheet itself is less liable to be deteriorated even when the piles are exposed on a fracture surface of the soft-feel layer. Thus, the key sheet with the piles is a key sheet excellent in durability.

In the key sheet of the second type, the hair-implanted layer may include a support layer for bonding one ends of the piles, and the piles are implanted in the support layer. When the support layer is formed on the base sheet or the skin layer and the piles are directly implanted with respect to the support layer, it is unnecessary to provide a pile sheet as a separate member. Thus, it is possible to realize a thin key sheet.

Further, when the support layer is translucent, it is possible to perform backlight illumination. With this, light easily transmits between the piles, and hence, when the layers other than the piles such as the base sheet, the skin layer, and the support layer are translucent, it is possible to provide a key sheet which has flexibility and is excellent in backlight illumination properties.

In the key sheet of the second type, all the display elements may be formed of a character layer including display portions and background portions formed by printing, the character layer being provided between the translucent skin layer and the translucent hair-implanted layer. That is, the character layer may be provided on the back surface of the skin layer. With the provision of the character layer on the back side of the skin layer, that is, the front side of the hair-implanted layer, fingers of an operator come into direct touch with the skin layer at the time of a pressing operation. Thus, it is possible to reliably provide a leather-like soft touch feeling. Further, it is possible to prevent abrasion of the character layer. In addition, the skin layer is translucent, and hence display elements are accurately visible.

Unlike the related art in which display elements formed of clipped portions are provided in the pressing-operation parts, the display elements constituted by the character layer are provided. Thus, it is possible to realize a key sheet less liable to be abraded and excellent in durability.

The character layer may include “display portions” and “background portions” forming peripheries of the display portions. Alternatively, in addition to the display portions and the background portions, the character layer may include a “frame portion” which is a portion except pressing-operation parts constituted by the display portions and the background portions and corresponds to a frame, or “partition portions” for partitioning the pressing-operation parts.

Further, in the character layer, both the display portions and the portions other than the display portions (background portions, for example) may be translucent, or any one of them may be lightproof. In addition, color tones therebetween may be different from each other even with substantially the same light transmittance. This is because the display portions are visible when the display portions and the portions other than the display portions are different from each other in light transmittance and color tone.

In the key sheet of the second type, the soft-feel layer may include through-holes as partition lines for partitioning the display elements. With the provision of the through-holes as the partition lines for partitioning the display elements, it is possible to cause the input operation parts to be more visible and possible to prevent misinputs. Further, backlight illuminates the key sheet also through the through-holes. Thus, it is possible to differentiate brightness of light transmitting through the display elements and brightness of light transmitting through the through-holes (partition lines) from each other. As a result, it is possible to provide a key sheet with characteristic illumination properties. Further, even when the character layer is not translucent, at least the display elements can be distinguished from each other with the illumination from the through-holes (partition lines).

In the key sheet of the second type, the piles may be made of a thermoplastic material, and compressed portions formed by flattening the piles in a thickness direction of the hair-implanted layer may be provided at edge portions of the hair-implanted layer. The fabric piles formed of a thermoplastic material such as a thermoplastic resin and thermoplastic elastomer are easily deformed or molten by ultrasonic welding or thermal-compression bonding in a pressurized state. Thus, the fabric piles are easily flattened in a thickness direction of the hair-implanted layer, and hence it is possible to provide the compressed portions in the hair-implanted layer. The compressed portions are formed by flattening the piles, and hence foams are hardly contained. As a result, a solid layer is formed. Thus, it is possible to prevent the compressed portions from wearing off unlike uncompressed hair-implanted layers even when being abraded, and from being eroded by chemicals, and hence the edge portions of the hair-implanted layer are prevented from suffering breakage even during use. Thus, it is possible to enhance durability of the hair-implanted layer.

In the key sheet of the second type, the skin layer may be extended so as to form protective portions for covering side surfaces of edge portions of the hair-implanted layer. With this, the hair-implanted layer is not exposed to the outside, and hence it is possible to enhance durability of the hair-implanted layer.

In the key sheet of the second type, instead of being formed of the character layer as described above, the display elements may be formed as follows.

Specifically, the display elements are constituted by display recessed-portions formed of recessed portions of the skin layer, constituted by display protruding-portions formed of protruding portions on the skin layer, or constituted by display holes formed of through-holes in the skin layer. With this, the display elements can be confirmed with touch feelings to the fingers.

In the key sheet of the second type, pressers protruding from a back surface of the pressing-operation parts in a pressing direction may be formed on the back surface. When a circuit board including disk-spring contacts is provided on the back surface side of the key sheet, the pressers protruding from the back surface are allowed to accurately press the disk-spring contacts. As a result, it is possible to realize a key sheet which enables a reliable pressing operation.

The present invention provides a key sheet of a third type, in which: the skin layer of the soft-feel layer has a back surface formed in an asperity shape of an inclined surface; each of the decorative portions of the soft-feel layer includes a first decorative layer formed on a back surface side of the skin layer and being non-uniform in layer thickness in recessed portions in the asperity shape, and a second decorative layer formed on a back surface side of the first decorative layer and having a color different from that of the first decorative layer; and an elastic layer is formed on a back surface side of the second decorative layer. With this, the soft-feel layer is provided on the front surface side of the base sheet, and the operating surface is constituted by the skin layer of the soft-feel layer. Thus, with a combination of the skin layer providing a soft touch feeling and the elastic layer slightly depressed at the time of a pressing operation, it is possible to realize a key sheet with a soft touch feeling.

Further, in the soft-feel layer, the first decorative layer is formed on the back surface side of the skin layer. The back surface of the skin layer is formed in an asperity shape of an inclined surface, and the first decorative layer is formed in a non-uniform layer thickness in recessed portions in the asperity shape. That is, the layer thickness of the first decorative layer is larger near bottoms of the recessed portions, and becomes gradually smaller toward protruding portions. Thus, it is possible to visualize gradual change in hue of the first decorative layer along with the asperity shape of the back surface of the skin layer. When the change in hue corresponds to change in color tone, it is possible to emphasize three-dimensionality of the outward appearance. Further, when the front surface of the skin layer is formed in conformity with the asperity shape of the back surface thereof, it is possible to realize richer three-dimensionality.

On the back surface side of the first decorative layer as described above, there is formed a second decorative layer of a color different from that of the first decorative layer. Thus, in portions smaller in layer thickness of the first decorative layer, a color tone of the second decorative layer is likely to emerge. As a result, in terms of outward appearance, it is possible to realize not only change in color tone of the first decorative layer, but also gradual change to different colors. For example, with combination of a blue first-decorative layer and a red second-decorative layer, it is possible to realize a color tone in which blue is gradually changed into red through bluish purple and purple red.

In the key sheet of the third type, a transparent and elastic medium layer for reducing a height difference in corrugation in the asperity shape may be provided on the back surface of the skin layer. With this, even when the back surface of the skin layer is formed as an asperity surface, it is possible to prevent edge portions of the first decorative layer from bleeding on the back surface side of the skin layer as long as height difference in corrugation in the asperity shape is small. Thus, it is possible to accurately provide the first decorative layer. Further, even with the provision of the medium layer, the medium layer is transparent, and hence the hue of the first decorative layer does not blur. In addition, the medium layer is elastic, and hence it is possible to avoid a soft touch feeling from being impaired.

In the key sheet of the third type, the first decorative layer may include a display layer for displaying display elements including letters, numerals, and symbols, and the soft-feel layer may include through-holes as partition lines for partitioning the display elements. With this, it is possible to partition the display elements with the through-holes, and hence possible to partition the display elements adjacent to each other and to cause the pressing-operation parts to be clearly visible. Further, the “partition lines” can be distinguished also with touch feelings.

In the key sheet of the third type, the second decorative layer may include a metallic layer containing metal. With this, it is possible to realize a key sheet with a brand-new design which has a metallic outward appearance and by which a soft touch feeling can be obtained at the time of a pressing operation. Note that, the metallic layer containing metal represents a coated layer containing foil of aluminum, gold, or the like, a metal-coated layer containing metal powder of aluminum, nickel, or the like, and a dry-plated layer formed of aluminum or indium.

In the key sheet of the third type, the elastic layer may include a porous layer, and protective portions for covering side surfaces of edge portions of the porous layer may be provided on the side surfaces thereof. With this, the porous layer is not exposed to the outside, and hence it is possible to enhance durability of the porous layer.

Further, when protective portions are provided also along the through-holes provided as partition lines in the soft-feel layer, the side surfaces of the porous layer are not exposed from the through-hole. Thus, it is possible to enhance durability of the porous layer.

In the key sheet of the third type, the base sheet and the second decorative layer may be translucent, and an EL member may be further provided on a back surface of the base sheet. With this, it is possible to illuminate the second decorative layer with plane light-emission, and hence possible to enhance visibility of the key sheet even in a dark place.

The present invention is capable of realizing a key sheet of a fourth type in which: the base sheet is translucent; the soft-feel layer further includes a porous layer laminated on a back surface side of the skin layer, the porous layer having a thickness ranging from 250 μm to 700 μm; and each of the decorative portions of the soft-feel layer includes first decorative portions provided between the skin layer and the porous layer and being visible through the skin layer, and second decorative portions provided on a back surface side of the porous layer and being visible with aid of light through the skin layer and the porous layer from the back surface side thereof. With this, the soft-feel layer is provided on the front surface side of the base sheet, and the operating surface is constituted by the skin layer of the soft-feel layer. Thus, it is possible to realize a key sheet which is capable of providing a soft touch feeling at the time of a pressing operation and which has a soft touch feeling.

Further, in the soft-feel layer, the first decorative portions are provided on the back surface side of the skin layer, and hence it is possible to prevent the first decorative portions from being abraded at the time of a pressing operation. The first decorative portions are visible through the translucent skin layer, and hence can be used as decorative portions of high visibility. In this context, when the first decorative portions are used as display portions indicating display elements such as letters and symbols, the display elements are clearly visible. Further, in the related art, display elements are formed of clipped portions, and hence clip holes are formed in the pressing-operation parts, which may cause rolling-up of the decorative sheet at the time of a pressing operation. However, in the present invention, such holes are not formed in the pressing-operation parts, and hence it is possible to realize a key sheet excellent in durability.

In the key sheet of the fourth type of the present invention, in the soft-feel layer, a porous layer having a thickness ranging from 250 μm to 700 μm is laminated on the back surface side of the skin layer. The porous layer is constituted by innumerable pores like a sponge and hence is unclear. Thus, the second decorative portions provided on the side opposite to the porous layer are less visible through the porous layer with light illuminated from behind an operator. In other words, in a non-illumination state in which a backlight source does not emit light, the second decorative portions provided on the back surface side of the porous layer are less visible to the operator through the porous layer from the operating surface side. Thus, in the non-illumination state, only the first decorative portions provided on the front surface side of the porous layer are visible to the operator. Meanwhile, in the illumination state in which the backlight source emits light, light illuminating the second decorative portions from the back surface side of the porous layer also illuminates the first decorative portions through the porous layer. Thus, at the time of illumination, the second decorative portions lit up together with the first decorative portions are visible to the operator. That is, it is possible to realize a key sheet with a brand-new design in which decorative designs can be switched between the illumination state and the non-illumination state.

The second decorative portions are visible even in the non-illumination state when the thickness of the porous layer is less than 250 μm, and the second decorative portions are less visible even in the illumination state when the thickness is more than 700 μm. As a result, it is impossible to switch the decorative designs between the illumination state and the non-illumination state.

Note that, when the porous layer is elastic, the operating surface of the soft-feel layer can be depressed more easily owing to flexibility of the porous layer. As a result, it is possible to further increase a soft touch feeling.

In the key sheet of the fourth type, the porous layer may include an open-cell foam layer in which foams are continuous with each other in a thickness direction. The “open-cell foam layer in which foams are continuous with each other in a thickness direction” represents a foam layer in which foams are continuous with each other in a thickness direction so as to emerge as longitudinal holes as illustrated, for example, in a photograph of FIG. 10, which was taken by a scanning electron microscope (SEM).

For example, in a closed-cell foam layer illustrated in a photograph of FIG. 51, which was taken by a scanning electron microscope, substantially spherical foams are formed at random. Thus, light transmitting therethrough is liable to be scattered, and hence the second decorative portions may become unclear at the time of illumination. In contrast, in the open-cell foam layer, light easily transmits through portions corresponding to the foams continuous with each other. Thus, when the porous layer includes the open-cell foam layer in which foams are continuous with each other in a thickness direction, light transmitting through the second decorative portions is allowed to transmit easily to the front surface side at the time of illumination. As a result, it is possible to cause the second decorative portions to be clearly visible. In this context, when the display elements are indicated by the second display portions, it is preferred that the porous layer be the open-cell foam layer in which foams are continuous with each other in the thickness direction. In addition, when the thickness of the porous layer ranges from 250 μm to 450 μm, even small display elements are clearly visible. The second decorative portions are visible even in the non-illumination state when the thickness of the porous layer is less than 250 μm, and the second decorative portions are less visible in the illumination state when the thickness is more than 450 μm.

In the key sheet of the fourth type, the front surface of the skin layer may be an asperity surface. With this, it is possible to reduce a frictional coefficient on the front surface of the skin layer, and possible to provide a smooth front surface. As a result, it is possible to increase a soft touch feeling.

Further, when the back surface of the skin layer is an asperity surface, it is possible to provide, on the asperity surface, an elastic and transparent medium layer which reduces a height difference in corrugation in the asperities. As in this case, even when the back surface of the skin layer is formed as an asperity surface, it is possible to accurately provide the first decorative portions on the back surface side of the skin layer as long as height difference in corrugation in the asperity shape is small. Thus, it is possible to realize a key sheet having clear display portions when the first decorative portions are provided as the display portions. In this context, even when the medium layer is provided, the medium layer is transparent, and hence the first decorative portions are prevented from being less visible. In addition, the medium layer is elastic, and hence a soft touch feeling is not impaired.

In the key sheet of the fourth type, the first decorative portions may include display portions for displaying display elements including letters, numerals, and symbols, and the soft-feel layer may include through-holes as partition lines for partitioning the display elements. With this, backlight transmits through the translucent base sheet so as to be emitted through the through-holes to the outside. Thus, it is possible to differentiate brilliance from the display portions and brilliance from the partition lines from each other. As a result, it is possible to realize a key sheet with characteristic illumination properties. Further, at least the display portions can be distinguished from each other with the illumination from the partition lines. Note that, herein, the “partition lines” for partitioning the display portions may partition one of the display portions from the other display portions like partition lines for partitioning display portions adjacent to each other, or may partition one of the pressing-operation parts constituted by display portions and background portions from the other parts of the pressing-operation parts and portions other than the pressing-operation parts.

When the partition lines are provided as described above, it is possible to cause the pressing-operation parts to be more visible and possible to prevent misinputs. Note that, both the display portions and the portions other than the display portions may be translucent, or any one of them may be lightproof. That is, the display portions are visible when light transmittance of the display portions and light transmittance of the portions other than the display portions are different from each other. Further, when color tones therebetween are different from each other even with substantially the same light transmittance, the display portions are visible. The shape of the partition lines is a shape allowing substantial definition of the pressing-operation parts. For example, there may be provided a shape of surrounding outer peripheries of the pressing-operation parts in a frame-like manner, a shape of forming a part of the outer peripheries of the pressing-operation parts, and the like. In this context, the through-holes are provided as the partition lines for defining pressing-operation parts, and hence the partition lines can be brightly illuminated. Further, the pressing-operation parts can be confirmed also with touch feelings owing to the partition lines. In addition, at the time of performing a pressing operation, the key sheet is easily deflected, and hence pressing load can be suppressed. As a result, it is possible to enhance pressing operability.

In the key sheet of the fourth type, protective portions for covering side surfaces of edge portions of the porous layer may be provided on the side surfaces thereof. With this, the porous layer is not exposed to the outside, and hence it is possible to enhance durability of the porous layer.

Further, when protective portions are provided also along the through-holes provided as partition lines in the soft-feel layer, the side surfaces of the porous layer are not exposed from the through-hole. Thus, it is possible to enhance durability of the porous layer.

In the key sheet of the fourth type, an EL member may be further provided on a back surface of the base sheet. With this, it is possible to uniformly illuminate the second decorative portions with plane light-emission, and hence possible to enhance visibility of the edge portions of the second decorative portions.

Further, a light guide plate may be further provided on the back surface of the base sheet. With this, it is possible to efficiently transmit backlight from a light source such as an LED or an EL. As a result, brightness can be enhanced.

### Effects of the Invention

According to the key sheet of the present invention, a soft touch feeling can be provided to an operator at the time of performing an input operation. Further, the decorative portions are provided on the back surface side of the translucent skin layer, and hence it is possible to enhance durability and visibility of the decorative portions. Further, in a case of being used as a so-called illumination-type key sheet which is illuminated with light emitted from the back surface side of the base sheet, the key sheet of the present invention may be provided with excellent illumination properties.

Further, according to the key sheet of the first type, the decorative portions are formed in the character layer having the printed layer in which display elements are formed, and hence it is possible to easily form the display elements by printing on the back surface of the skin layer.

Further, according to the key sheet of the second type, which is constituted by the translucent base sheet, the translucent hair-implanted layer, and the translucent skin layer, it is possible to realize a key sheet excellent in visibility of display elements even in a dark place. Further, it is possible to perform illumination with the leather-like outward appearance, and hence possible to realize a key sheet excellent in design, which is more warm and looks alive.

Further, according to the key sheet of the third type, it is possible to visualize gradual change in hue of the first decorative layer along with the asperity shape of the back surface of the skin layer. When the change in hue corresponds to change in color tone, it is possible to emphasize three-dimensionality of the outward appearance. Further, in the portions smaller in layer thickness of the first decorative layer, the color tone of the second decorative layer is likely to emerge. As a result, in terms of outward appearance, it is possible to realize not only change in color tone of the first decorative layer, but also gradual change to different colors.

Further, according to the key sheet of the fourth type, the soft-feel layer is provided on the front surface side of the base sheet, and hence it is possible to provide a soft touch feeling at the time of a pressing operation. Thus, it is possible to realize a thin key sheet with a soft touch feeling. Further, the first decorative portions are not abraded at the time of a pressing operation, and no holes are formed in the pressing-operation parts in the soft-feel layer. Thus, it is possible to realize a key sheet excellent in durability. In addition, it is possible to change a design of the key sheet so as to provide different outward appearances between an illumination state and a non-illumination state, and hence possible to realize a key sheet with a brand-new design.

### BRIEF DESCRIPTION OF THE DRAWINGS

FIG. 1 is a plan view of a key sheet according to a first embodiment of the present invention.

FIG. 2 is a sectional view taken along the line SA-SA of FIG. 1.

FIG. 3 is a sectional view of a key sheet according to a second embodiment of the present invention, which corresponds to FIG. 2.

FIG. 4 is a sectional view illustrating a first modification of the key sheet according to the second embodiment, which corresponds to FIG. 2.

FIG. 5 is a plan view of a key sheet according to a third embodiment of the present invention.

FIG. 6 is a sectional view taken along the line SB-SB of FIG. 5.

FIG. 7 is a plan view of a key sheet according to a fourth embodiment of the present invention.

FIG. 8 is a sectional view taken along the line SC-SC of FIG. 7.

FIG. 9 are plan views illustrating other shapes of partition portions used in the key sheet of the present invention.

FIG. 10 is a sectional view of a key sheet according to a fifth embodiment of the present invention, which corresponds to FIG. 2.

FIG. 11 is a sectional view illustrating a second modification of the key sheet according to the fifth embodiment, which corresponds to FIG. 2.

FIG. 12 is a key sheet according to a sixth embodiment of the present invention, which corresponds to FIG. 2.

FIG. 13 is a plan view of a key sheet according to a seventh embodiment of the present invention.

FIG. 14 is a sectional view taken along the line SD-SD of FIG. 13.

FIG. 15 is a plan view of a key sheet according to an eighth embodiment of the present invention.

FIG. 16 is a sectional view taken along the line SE-SE of FIG. 15.

FIG. 17 is a partially enlarged sectional view of the part R of FIG. 16, which illustrates the eighth embodiment.

FIG. 18 is an explanatory view of a case where a finger touches the key sheet according to the eighth embodiment.

FIG. 19 is a sectional view of a key sheet according to a ninth embodiment of the present invention, which corresponds to FIG. 16.

FIG. 20 is a plan view of a key sheet according to a tenth embodiment of the present invention.

FIG. 21 is a sectional view taken along the line SF-SF of FIG. 20.

FIG. 22 is sectional view of a key sheet according to an eleventh embodiment of the present invention, which corresponds to FIG. 16.

FIG. 23 is a partially enlarged sectional view of the key sheet of a first modification common to the eighth to eleventh embodiments.

FIG. 24 is a sectional view of the key sheet of a second modification common to the eighth to eleventh embodiments, which corresponds to FIG. 16.

FIG. 25 is a sectional view of the key sheet of a third modification common to the eighth to eleventh embodiments, which corresponds to FIG. 16.

FIG. 26 is a sectional view of the key sheet of a fourth modification common to the eighth to eleventh embodiments, which corresponds to FIG. 16.

FIG. 27 is a sectional view of the key sheet of a fifth modification common to the eighth to eleventh embodiments, which corresponds to FIG. 16.

FIG. 28 is a sectional view of the key sheet of a sixth modification common to the eighth to eleventh embodiments, which corresponds to FIG. 16.

FIG. 29 is an explanatory view of a brightness measurement method.

FIG. 30 is a graph showing brightness measurement results.

FIG. 31 is a plan view of a key sheet according to a twelfth embodiment of the present invention.

FIG. 32 is a sectional view taken along the line SG-SG of FIG. 31.

FIG. 33 is a sectional view taken along the line SH-SH of FIG. 31.

FIG. 34 are partially enlarged sectional views of a first decorative layer and a second decorative layer.

FIG. 35 is a sectional view of a key sheet according to a thirteenth embodiment of the present invention, which corresponds to FIG. 33.

FIG. 36 is a partially enlarged sectional view of a medium layer, the first decorative layer, and the second decorative layer.

FIG. 37 is a sectional view of a key sheet according to a fourteenth embodiment of the present invention, which corresponds to FIG. 33.

FIG. 38 is a sectional view of a key sheet according to a fifteenth embodiment of the present invention, which corresponds to FIG. 33.

FIG. 39 is a sectional view of a key sheet according to a sixteenth embodiment of the present invention, which corresponds to FIG. 33.

FIG. 40 is a sectional view of a key sheet according to a seventeenth embodiment of the present invention, which corresponds to FIG. 33.

FIG. 41 is a plan view of a key sheet according to an eighteenth embodiment of the present invention.

FIG. 42 is a sectional view taken along the line SI-SI of FIG. 41.

FIG. 43 is a plan view of the key sheet according to the eighteenth embodiment in an illumination state.

FIG. 44 is a plan view of a key sheet according to a nineteenth embodiment of the present invention.

FIG. 45 is a sectional view taken along the line SJ-SJ of FIG. 44.

FIG. 46 is a plan view of the key sheet according to the nineteenth embodiment in an illumination state.

FIG. 47 is a sectional view of a key sheet according to a twentieth embodiment of the present invention, which corresponds to FIG. 42.

FIG. 48 is a sectional view of a key sheet according to a twenty-first embodiment of the present invention, which corresponds to FIG. 42.

FIG. 49 is a sectional view of a key sheet according to a twenty-second embodiment of the present invention, which corresponds to FIG. 42.

FIG. 50 is a photomicrograph of a porous layer constituted by an open-cell foam layer.

FIG. 51 is a photomicrograph of a porous layer constituted by a closed-cell foam layer.

### DESCRIPTION OF SYMBOLS

1 key sheet (first embodiment)

2 skin layer
2a surface (operating surface)
2b back surface

3 character layer
3a display portion
3b background portion

4 bonding layer

5 base sheet

6 key sheet (first modification of first embodiment)

7 key sheet (second modification of first embodiment)

9 key sheet (second embodiment)

10 key sheet (first modification of second embodiment)

11 key sheet (second modification of second embodiment)

12 bonding layer

14 key sheet (third embodiment)

15 character layer
15a display portion
15b frame portion
15c background portion

16 bonding layer (decorative layer)

17 input operation part

18 key sheet (first modification of third embodiment)

19 key sheet (fourth embodiment)

21 character layer
21a display portion

121b frame portion
21c background portion
21d partition portion

22 key sheet (first modification of fourth embodiment)

23 key sheet (fifth embodiment)

24 skin layer
24a back surface

25 character layer
25a display portion
25b frame portion
25c background portion

27 partition portion (through-hole)
27a bulge

29 key sheet (first modification of fifth embodiment)

30 key sheet (second modification of fifth embodiment)

31 character layer
31a display portion

32 decorative layer

33 key sheet (sixth embodiment)

34 skin layer
34a protective portion

35 foam layer

41 key sheet (seventh embodiment)

42 skin layer
42a back surface portion

43 character layer
43a display portion
43b frame portion
43c background portion

45 foam layer

51 key sheet (eighth embodiment)

52 soft-feel layer

53 base sheet
53a front surface
53b back surface

54 skin layer
54a front surface
54b back surface

55 character layer
55a display portion
55b background portion
55c partition line

56 bonding layer

57 hair-implanted layer
57a support layer
57b pile

58 pressing-operation part

59 key sheet (ninth embodiment)

60 soft-feel layer

61 skin layer
61a front surface
61b back surface

62 character layer
62a display portion
62b background portion

63 bonding layer

64 hair-implanted layer

65 through-hole (partition line)

66 key sheet (tenth embodiment)

67 soft-feel layer

68 skin layer
68a front surface
68b back surface
68c stepped surface

69 character layer
69a display portion
69b background portion

70 bonding layer

71 hair-implanted layer
71c compressed portion

72 key sheet (eleventh embodiment)

73 soft-feel layer

74 skin layer
74a front surface
74b back surface
74c protective portion

75 key sheet (first modification of eighth embodiment)

76 key sheet (second modification of eighth embodiment)

77 character layer
77a display portion
77b background portion
77c partition line

78 key sheet (third modification of eighth embodiment)

79 character layer
79a display portion
79b background portion
79c partition line

80 key sheet (fourth modification of eighth embodiment)

81 skin layer
81a front surface
81b back surface
81c display recessed portion

82 application layer

83 key sheet (fifth modification of eighth embodiment)

84 skin layer
84b back surface
84c display hole

85 key sheet (sixth modification of eighth embodiment)

86 presser

90 light table

91 masking sheet

92 brightness detector

101 key sheet (twelfth embodiment)

102 base sheet

103 soft-feel layer

104 skin layer

105 first decorative layer

106 second decorative layer

107 porous layer (elastic layer)

108a background portion

108b display portion

108c partition line

109 pressing-operation part

110 bonding layer

111 first decorative layer (first modification)

112 first decorative layer (second modification)

113 first decorative layer (third modification)

114 first decorative layer (fourth modification)

115 second decorative layer (modification)

116 bonding layer (modification)

117 porous layer (modification)

118 key sheet (thirteenth embodiment)

119 soft-feel layer

120 medium layer

121 key sheet (fourteenth embodiment)

122 soft-feel layer

123 first decorative layer

124 second decorative layer

125 key sheet (fifteenth embodiment)

126 soft-feel layer

127 through-hole (partition lien)

128 skin layer

129 medium layer

130 first decorative layer

131 second decorative layer

132 porous layer

133 bonding layer

134 key sheet (sixteenth embodiment)

135 soft-feel layer

136 skin layer
136a protective portion

137 key sheet (seventeenth embodiment)

138 EL member

151 key sheet (eighteenth embodiment)

152 base sheet

153 soft-feel layer

154 skin layer

155 first decorative portion
155a display portion
155b partition line

156 bonding layer

157 porous layer

158 bonding layer

159 second decorative portion
159a display portion

160 pressing-operation part

161 key sheet (nineteenth embodiment)

162 soft-feel layer

163 skin layer

164 first decorative portion
164a display portion

165 second decorative portion
165a partition line

166 medium layer

167 key sheet (twentieth embodiment)

168 soft-feel layer

169 through-hole

170 skin layer

171 first decorative portion

172 bonding layer

173 porous layer

174 bonding layer

175 key sheet (twenty-first embodiment)

176 soft-feel layer

177 skin layer
177a protective portion

178 key sheet (twenty-second embodiment)

179 EL member

### BEST MODES FOR CARRYING OUT THE INVENTION

In the following, description is made of embodiments of the present invention with reference to drawings. A key sheet of a first type is described in first to seventh embodiments, a key sheet of a second type in eighth to eleventh embodiments, a key sheet of a third type in thirteenth to seventeenth embodiments, and a key sheet of a fourth type in eighteenth to twenty-second embodiments. Note that, redundant description of the members, materials, structure, manufacturing methods, and actions and effects common in the embodiments is omitted.

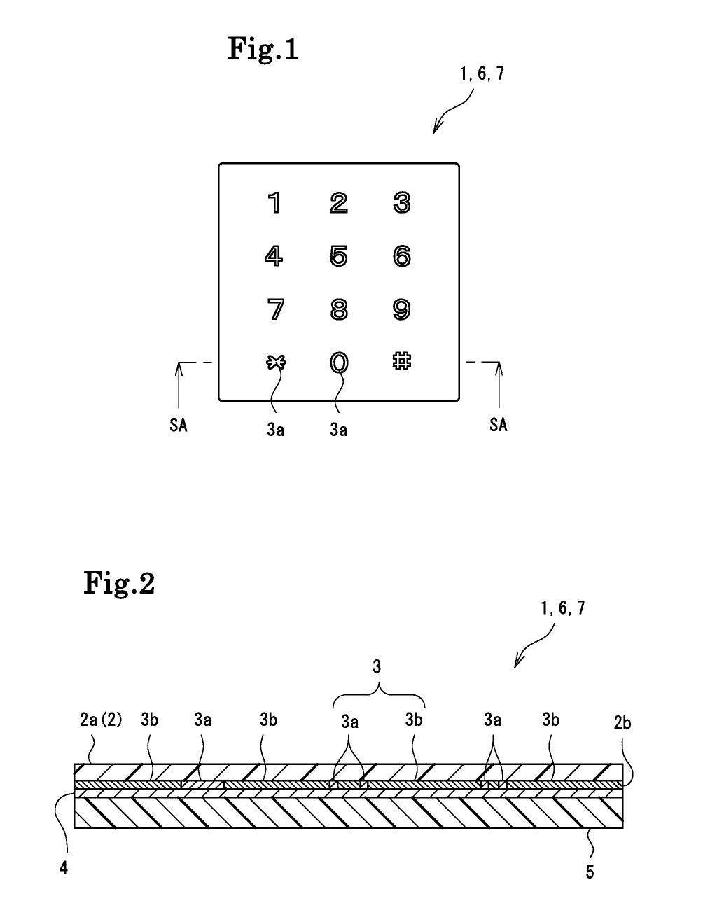

### First Embodiment (FIGS. 1 and 2)

FIGS. 1 and 2 illustrate a key sheet 1 according to the first embodiment. FIG. 1 is a plan view of the key sheet 1, and FIG. 2 is a sectional view of the key sheet 1, which is taken along the line SA-SA. The key sheet 1 according to the first embodiment includes a soft-feel layer constituted by a skin layer 2 and a character layer 3, a bonding layer 4, and a base sheet 5. The skin layer 2, the character layer 3, the bonding layer 4, and the base sheet 5 are laminated in the stated order from an operating surface side.

The skin layer 2 is a layer providing a leather-like soft touch feeling, and is formed of a translucent polymer material to be formed into a sheet. As a material for the skin layer 2, there may be used a resin or elastomer excellent in abrasion resistance, waterproofness, and chemical resistance. Examples thereof include polyolefin-based resins such as polyethylene and polypropylene, polystyrene-based resins such as polystyrene and a styrene-maleic anhydride copolymer, polyurethane-based resins, polyvinyl chloride-based resins, and thermoplastic elastomers. Of those, excellent soft touch feeling can be obtained when using polyurethane-based resins.

In addition, it is possible to use resin components obtained by mixing expandable beads, hollow beads, elastic beads, inorganic materials, or the like with the resins or the elastomer. With addition of the beads and the inorganic materials, it is possible to form asperities on the skin layer 2 so as to provide various touch feelings. The expandable beads are beads that become hollow when heated, and as a material for the expandable beads, there are exemplified polyurethane, an acrylic-urethane copolymer, polystyrene, and a styrene-isoprene copolymer. The hollow beads are a hollow spherical object, and as a material for the hollow beads, there are exemplified copolymers of vinylidene chloride and acrylonitrile and a across-linked acrylic polymer. The elastic beads are resin particles which have an elastic recovery property, when pressure is applied until a shape of the beads changes and then released. Examples thereof include polyurethane resins, acrylic-urethane resins, polystyrene resins, and a styrene-isoprene copolymer. Examples of the inorganic materials include silicon dioxide (SiO₂; also referred to as silica and silicic anhydride), hydrous silicate (SiO₂·xH₂O), and hydrous aluminum silicate (Al₂O₃9SiO₂·xH₂O).

Further, with use of a mold-release sheet or a die, it is possible to transfer and mold an asperity pattern onto the operating surface of the skin layer 2 so as to achieve a smooth touch feeling. In addition, to the above-mentioned resin components, there may be added various additives including a colorant such as a pigment or a dye, an antioxidant, and an ultraviolet absorber in some cases. Similarly, the above-mentioned resins or elastomer may be mixed with various additives including a colorant such as a pigment or a dye, an antioxidant, and an ultraviolet absorber. It is preferred that a thickness of the skin layer 2 as described above range from 5 μm to 200 μm. This is because the skin layer 2 having a thickness of less than 5 μm is liable to suffer breakage owing to its poor durability and the skin layer 2 having a thickness of more than 200 μm impairs a touch feeling with respect to the operator owing to its high rigidity, which leads to difficulty in achieving the soft touch feeling.

The character layer 3 is an application layer formed by printing, and is constituted by display portions 3a displaying patterns of display elements such as letters, numerals, and symbols and background portions 3b forming peripheries of the display portions 3a. Both the display portions 3a and the background portions 3b are translucent, and hence the display portions 3a and the background portions 3b constitute “translucent portions” which allow passage of light. Note that, light transmittance of the display portions 3a is higher than light transmittance of the background portions 3b, and hence the display portions 3a are illuminated more brightly in a case of adopting so-called backlight illumination.

As a material for the character layer 3, there may be used an ink or a paint applicable to a back surface 2b of the skin layer 2. Note that, when the character layer 3 has a property of exhibiting adhesiveness after being molded through application as in a case of a hot-melt adhesive, the boning layer 4 specifically described below may be omitted.

The bonding layer 4 is a layer for bonding the character layer 3 and the base sheet 5 to each other, and is formed of a translucent adhesive or a translucent pressure-sensitive adhesive. Examples of the usable translucent adhesives include an adhesive film, a pressure-sensitive adhesive film, and a hot-melt adhesive.

The base sheet 5 has a function of providing formability of the key sheet 1, and is formed of a translucent resin. With provision of pressers on a back surface of the base sheet 5, it is possible to enhance pressing operability. The base sheet 5 may be formed of a translucent thermoplastic resin and a thermosetting resin. Examples of the translucent resins include an acrylic resin, a styrene resin, a polyester resin, a polyolefin resin, a silicone resin, an epoxy resin, and a urethane-based resin. It is preferred that a thickness of the base sheet 5 as described above range from 100 μm to 500 μm. This is because the base sheet 5 having a thickness of less than 100 μm may suffer breakage in post-processing owing to its poor strength, and has difficulty in maintaining a shape of the key sheet 1 owing to its poor rigidity. The base sheet 5 having a thickness of more than 500 μm is difficult to deflect owing to its high rigidity, which leads to an increase in pressing load so as to deteriorate operability in a case of a key sheet for an operation by pressing input.

The key sheet 1 is manufactured by molding the character layer 3 through application on the back surface 2b of the skin layer 2, and then performing laminating on the character layer 3 and the base sheet 5 between which an adhesive film constituting the bonding layer 4 is sandwiched. In this way, the layers are laminated and bonded to each other so as to obtain the key sheet 1.

The key sheet 1 is provided with the skin layer 2 on an operating surface thereof, and hence an operator can obtain a soft touch feeling at the time of performing an input operation. The character layer 3 is provided on the back surface 2b of the translucent skin layer 2, and hence it is possible to enhance visibility of the display portions 3a while preventing abrasion of the display portions 3a. Further, the display portions 3a can be illuminated by light transmitting through the bonding layer 4 and the base sheet 5 laminated on the back surface side of the character layer 3. Thus, in the case of adopting so-called backlight illumination by providing a light source on a back surface side of the base sheet 5, the display portions 3a can be illuminated by the light from the light source. As a result, it is possible to realize a key sheet 1 which has the display portions 3a excellent in soft touch feeling and durability and which can be illuminated.

The display portions 3a of the character layer 3 constitute the translucent portions, and hence the display portions 3a can be brightly illuminated by the light transmitting through the bonding layer 4 and the base sheet 5. Thus, it is possible to realize an illumination-type key sheet 1 in which the visibility of the display portions 3a is enhanced.

In addition, the background portions 3b of the character layer 3 constitute the translucent portions, and hence the entire key sheet 1 can be brightly illuminated by the light transmitting through the bonding layer 4 and the base sheet 5. In this context, the display portions 3a and the background portions 3b are different from each other in transmittance, and hence it is possible to realize a key sheet 1 in which the display portions 3a are illuminated more brightly than the background portions 3b.

### First Modification of First Embodiment

The background portions 3b are translucent in the key sheet 1 according to the first embodiment. Meanwhile, the background portions 3b are lightproof in a key sheet 6 of this modification. With this, it is possible to make brightness of the display portions 3a distinguished, and hence possible to cause the display portions 3a to be clearly visible. In this manner, it is possible to realize a key sheet 6 in which input operability is enhanced.

### Second Modification of First Embodiment

The display portions 3a are lightproof in a key sheet 7 of this modification. With this, it is possible to make brightness of the display portions 3a distinguished, and hence possible to cause the background portions 3b of blank-character patterns to be clearly visible. In this manner, it is possible to realize a key sheet 7 in which input operability is enhanced.

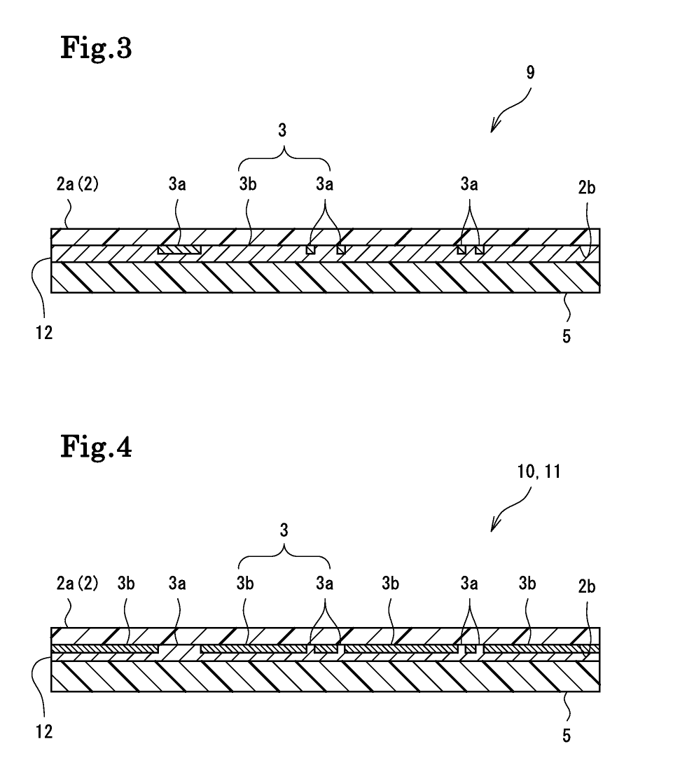

### Second Embodiment (FIG. 3)

FIG. 3 illustrates a key sheet 9 according to the second embodiment. FIG. 3 is a sectional view of the key sheet 9. In this embodiment, a part of the character layer doubles as a bonding layer for bonding the skin layer 2 and the base sheet 5 to each other. In this regard, the key sheet 9 according to the second embodiment is different from the key sheets 1, 6, and 7 according to the first embodiment, in which the bonding layer 4 is provided separately from the character layer 3. That is, in the key sheet 9 according to this embodiment, the background portion 3b is constituted by a bonding layer 12. With this, the bonding layer 12 is capable of doubling as a background of the display portions 3a. As a result, it is possible to realize a key sheet 7 at lower cost with simplified manufacture.

### First Modification of Second Embodiment (FIG. 4)

FIG. 4 is a sectional view of a key sheet 10 of this modification. In this modification, the display portions 3a are constituted by the bonding layer 12. That is, the character layer 3 is constituted by the background portions 3b and the bonding layer 12 forming the display portions 3a. With this, the bonding layer 12 is capable of doubling as the display portions 3a. As a result, it is possible to realize a key sheet 7 at lower cost with simplified manufacture. In this context, when the background portions 3b are lightproof and the bonding layer 12 constituting the display portions 3a is translucent, illumination can be performed through the display portions 3a.

### Second Modification of Second Embodiment

A key sheet 11 of this modification is structurally similar to the key sheet 10 of the first modification of the second embodiment. However, the key sheet 11 of this modification is different therefrom in that the background portions 3b are also translucent. Both the display portions 3a and the background portions 3b are translucent, and hence the entire key sheet 11 can be illuminated. Further, through changes in transmittance and color tone of the display portions 3a and the background portions 3b, it is possible to realize various designs.

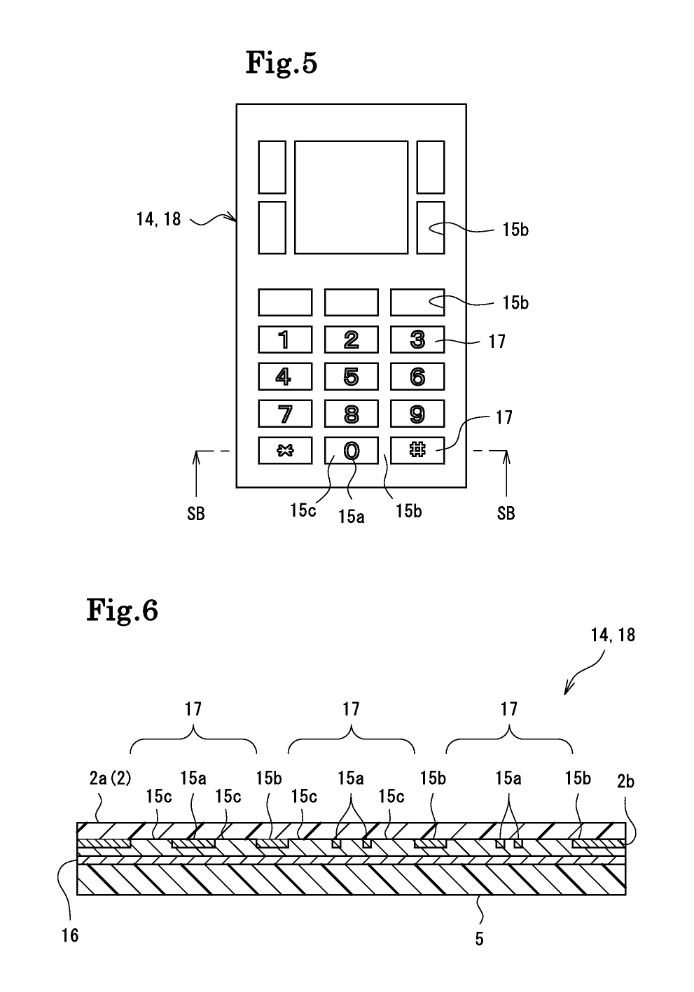

### Third Embodiment (FIGS. 5 and 6)

FIGS. 5 and 6 illustrate a key sheet 14 according to the third embodiment. FIG. 5 is a plan view of the key sheet 14, and FIG. 6 is a sectional view of the key sheet 14, which is taken along the line SB-SB. The key sheet 14 according to the third embodiment is structurally different from the key sheet 9 according to the second embodiment in that a character layer 15 is provided with a frame portion 15b in addition to display portions 15a and background portions 15c. The frame portion 15b is a frame part which is not subjected to a pressing operation unlike pressing-operation parts 17 constituted by the display portions 15a and the background portions 15c. Further, a bonding layer 16 is constituted as a “decorative layer” for performing decoration by changing color tone of the character layer 15.

Similarly to the key sheet 9 according to the second embodiment, the key sheet 14 is manufactured by molding the character layer 15 through application on the back surface 2b of the skin layer 2. The display portions 15a and the frame portion 15b are collectively coated with the same ink. After that, the decorative layer 16 is formed through application on a back surface of the character layer 15, and the key sheet 14 is obtained by laminating those layers.

According to the key sheet 14 of this embodiment, the input operation parts 17 are partitioned by the frame portion 15b, and hence it is possible to cause the input operation parts 17 to be more visible and possible to prevent misinputs. Further, when all of the display portions 15a, the frame portion 15b, and the background portions 15c are constituted as “translucent portions,” the entire key sheet 14 can be brightly illuminated. In this manner, it is possible to realize a key sheet 14 in which input operability is enhanced.

### First Modification of Third Embodiment

In a key sheet 18 of this modification, the display portions 15a and the frame portion 15b are constituted as the “translucent portions.” With this, it is possible to make brightness of the background portions 15c distinguished, and hence possible to cause the display portions to be clearly visible as blank-character patterns. In this manner, it is possible to realize a key sheet 18 in which input operability is enhanced.

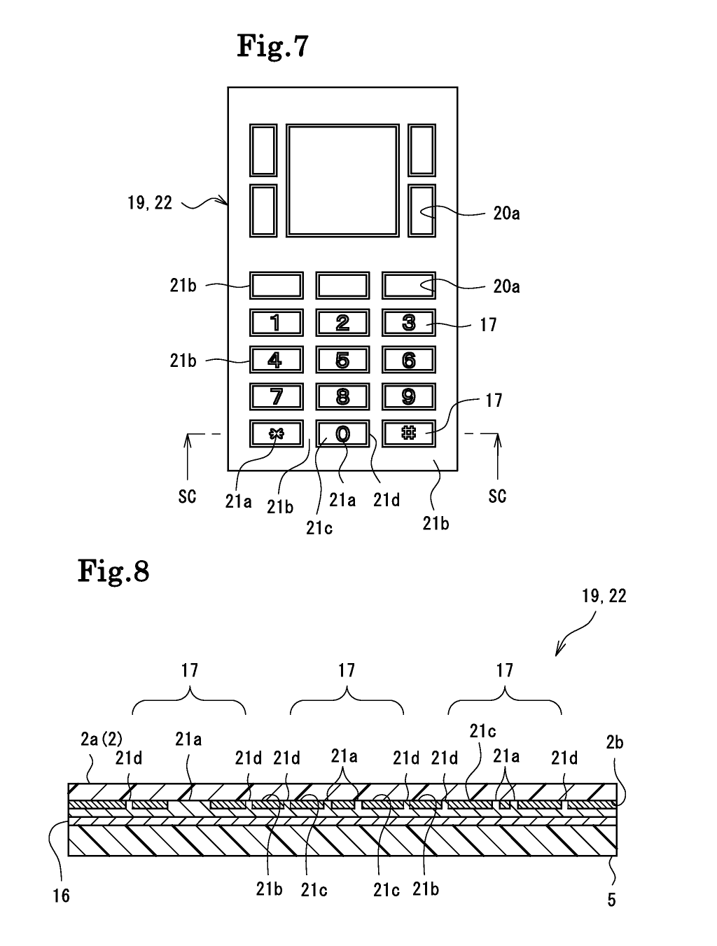

### Fourth Embodiment (FIGS. 7 and 8)

FIGS. 7 and 8 illustrate a key sheet 19 according to the fourth embodiment. FIG. 7 is a plan view of the key sheet 19, and FIG. 8 is a sectional view of the key sheet 19, which is taken along the line SC-SC. The key sheet 19 according to the fourth embodiment is structurally different from the key sheet 14 according to the third embodiment in that a character layer 21 is additionally provided with partition portions 21d. The partition portions 21d are provided for partitioning the pressing-operation parts 17 constituted by display portions 21a and background portions 21c, that is, serve as partition lines for partitioning the display portions. According to the key sheet 19, when the character layer 21 and the bonding layer 16 constituting the decorative layer are translucent, the entire key sheet 19 can be brightly illuminated.

### First Modification of Fourth Embodiment

The character layer 21 is constituted as a “translucent portion” in the key sheet 19 according to the fourth embodiment. Meanwhile, in a key sheet 22 of this modification, the background portions 21c and a frame portion 21b of the character layer 21 are constituted as “lightproof portions,” and the display portions 21a and the partition portions 21d are constituted as “translucent portions.” With this, it is possible to make brightness of the display portions 21a and the partition portions 21d distinguished, and hence possible to cause the display portions 21a to be clearly visible. In this manner, it is possible to realize a key sheet 22 in which input operability is enhanced.

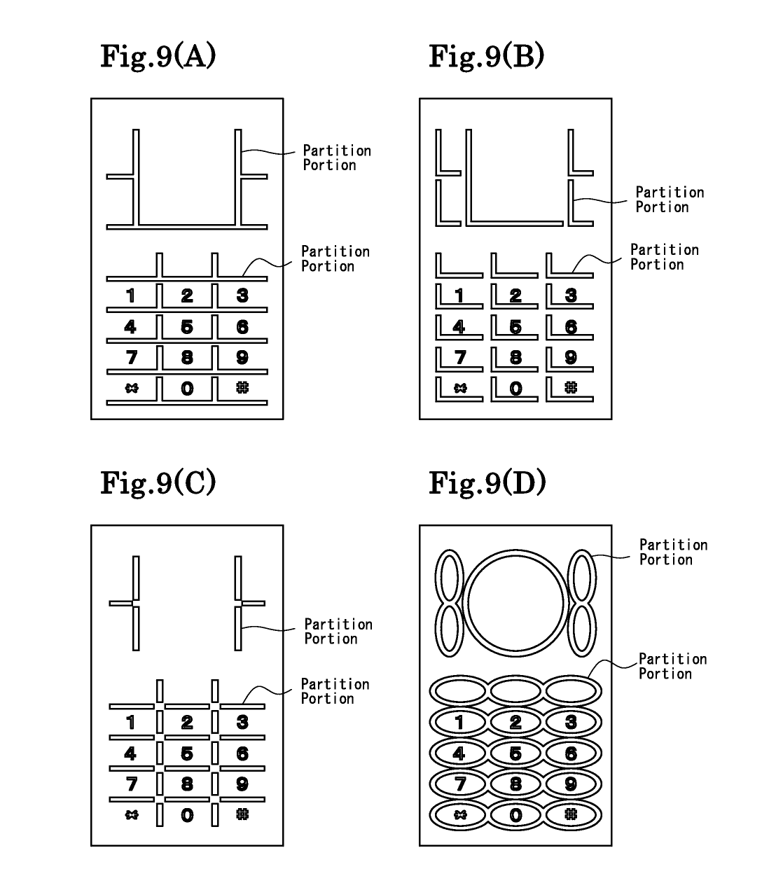

### Modification of Partition Portion in Fourth Embodiment (FIG. 9)

The case is exemplified where the partition portions 21d rectangularly surround the input operation parts 17 in the key sheet 19 according to the fourth embodiment. Meanwhile, partition portions as described below may be formed as partition lines.

As illustrated in FIG. 9(A), the input operation parts 17 can be defined by long/short linear partition portions crossing with each other. As illustrated in FIG. 9(B), the input operation parts 17 can be defined by L-shaped partition portions. As illustrated in FIG. 9(C), the input operation parts 17 can be defined by short linear partition portions. As illustrated in FIG. 9(D), the input operation parts 17 can be defined by elliptical/circular partition portions crossing with each other.

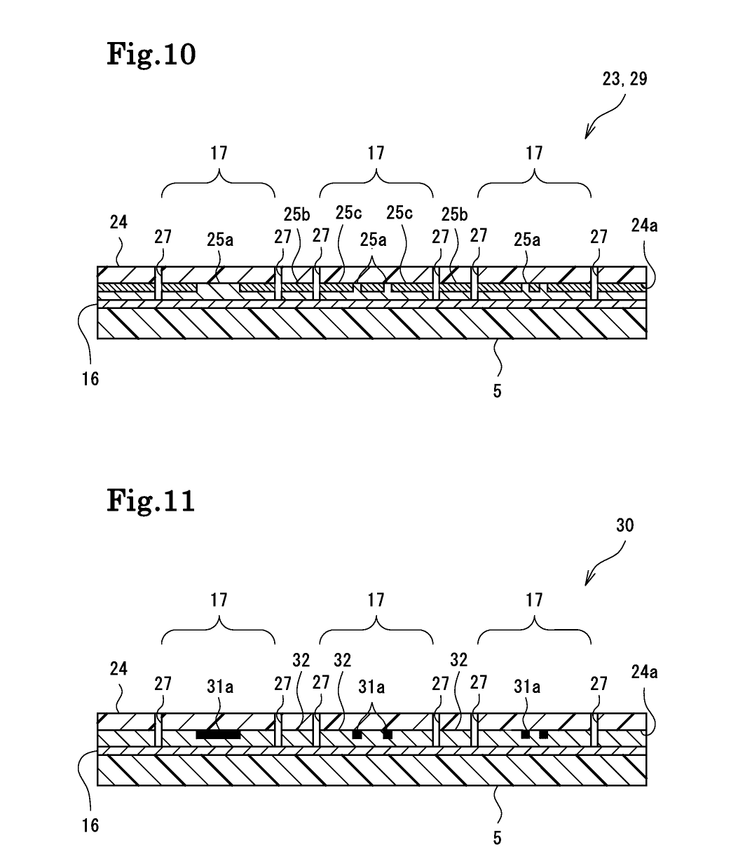

### Fifth Embodiment (FIG. 10)

FIG. 10 illustrates a key sheet 23 according to the fifth embodiment. FIG. 10 is a sectional view of the key sheet 23, which is taken along the line SD-SD. The key sheet 23 according to the fifth embodiment is structurally different from the key sheet 19 according to the fourth embodiment in structure of partition portions. That is, in this embodiment, partition portions 27 are constituted not as a part of a character layer 25 but as through-holes 27 passing through a soft-feel layer constituted by a skin layer 24 and the character layer 25 in a thickness direction thereof.

Similarly to the other embodiments, the key sheet 23 is manufactured by forming the character layer 25 through application on the skin layer 24, and then performing laminating on the base sheet 5 with use of an adhesive film constituting the bonding layer 16. After that, a blade is applied from above the skin layer 24 so as to form the partition portions 27, that is, the through-holes passing through the skin layer 24 and the character layer 25. In this manner, the key sheet 23 is obtained. Note that, the partition portions 27 may be formed prior to laminating, and may be formed as through-holes reaching the bonding layer 16.

According to the key sheet 23, when the character layer 25 and the bonding layer 16 are translucent, the entire key sheet 23 can be brightly illuminated. In this context, light is emitted through the partition portions 27 without being emitted through the skin layer 24 or the character layer 25, and hence the partition portions 27 can be illuminated more brightly than display portions 25a. Thus, it is possible to realize an illumination-type key sheet 23 in which the visibility of the pressing-operation parts 17 is enhanced. Further, at the time of performing an input operation, the key sheet 23 is easily deflected because the partition portions 27 pass through the skin layer 24 and the character layer 25, and hence pressing load can be suppressed. In this manner, it is possible to enhance pressing operability.

### First Modification of Fifth Embodiment

While the case is exemplified where the display portions 25a and background portions 25c corresponding to the input operation parts 17 are constituted as “translucent portions” in the key sheet 23 according to the fifth embodiment, the background portions 25c are constituted as “lightproof portions” in a key sheet 29 of this modification. With this, it is possible to make brightness of the display portions 25a distinguished, and hence possible to cause the display portions 25a to be clearly visible. In this manner, it is possible to realize a key sheet 29 in which input operability is enhanced.

### Second Modification of Fifth Embodiment (FIG. 11)

FIG. 11 is a sectional view of a key sheet 30 of this modification. While the case is exemplified where the display portions 25a and the background portions 25c corresponding to the input operation parts 17 are constituted as “translucent portions” in the key sheet 23 according to the fifth embodiment, display portions 31a are constituted as “lightproof portions” in the key sheet 30 of this modification. With this, it is possible to make brightness of a decorative layer 32 around the display portions 31a distinguished, and hence possible to perform illumination in blank-character patterns.

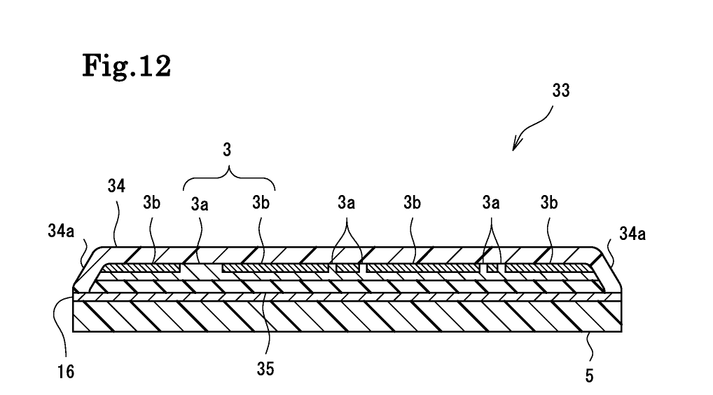

### Sixth Embodiment (FIG. 12)

FIG. 12 illustrates a key sheet 33 according to the sixth embodiment. FIG. 12 is a sectional view of the key sheet 33. Unlike the key sheet 10 illustrated in FIG. 4, the key sheet 33 according to this embodiment further includes a foam layer 35 as a “porous layer.” That is, in the key sheet 33 according to this embodiment, a soft-feel layer is constituted by a skin layer 34, the character layer 3, and the foam layer 35. Further, the skin layer 34 according to this embodiment has an outer edge portion extending and being inclined in a flared manner so as to form a protective portion 34a for covering a side surface of an edge portion of each of the character layer 3 and the foam layer 35. The protective portion 34a extends to the bonding layer 16.

A material for the foam layer 35 is a resin or an elastomer which may be formed into a foam, and similarly to the material for the skin layer 34, there are exemplified polyolefin-based resins such as polyethylene and polypropylene, polystyrene-based resins such as a polystyrene and styrene-maleic anhydride copolymer, polyurethane-based resins, polyvinyl chloride-based resins, and thermoplastic elastomers. The foam layer 35 in this embodiment is provided with translucency by reducing a thickness of the foam layer 35 or lowering a degree of foaming.

The key sheet 33 is manufactured by forming the character layer 3 and the foam layer 35 through lamination on the skin layer 34, and then performing laminating on the soft-feel layer and the base sheet 5 with use of an adhesive film constituting the bonding layer 16. Next, by thermal-compression bonding or ultrasonic welding, a jig is pressed from the skin layer 34 side onto the sheet thus obtained so as to compress the foam layer 2 in a thickness direction in a flattening manner before cutting the sheet. In this manner, the key sheet 33 is obtained.

According to the key sheet 33, the foam layer 35 is provided between the character layer 3 and the base sheet 5, and hence an operating surface of the skin layer 34 can be depressed more easily owing to flexibility of the foam layer 35. As a result, it is possible to further increase a soft touch feeling. Further, the foam layer 35 has translucency, and hence the display portions 3a can be illuminated. In addition, the side surface of the edge portion of the foam layer 35 is protected by the protective portion 34a of the skin layer 34 so as not to expose the foam layer 35, and hence it is possible to enhance durability thereof. Still further, the character layer 3 is formed on the upper surface of the foam layer 35, and hence the character layer 3 is visible without interference of the foam layer 35. As a result, the display portions 3a excellent in visibility are obtained.

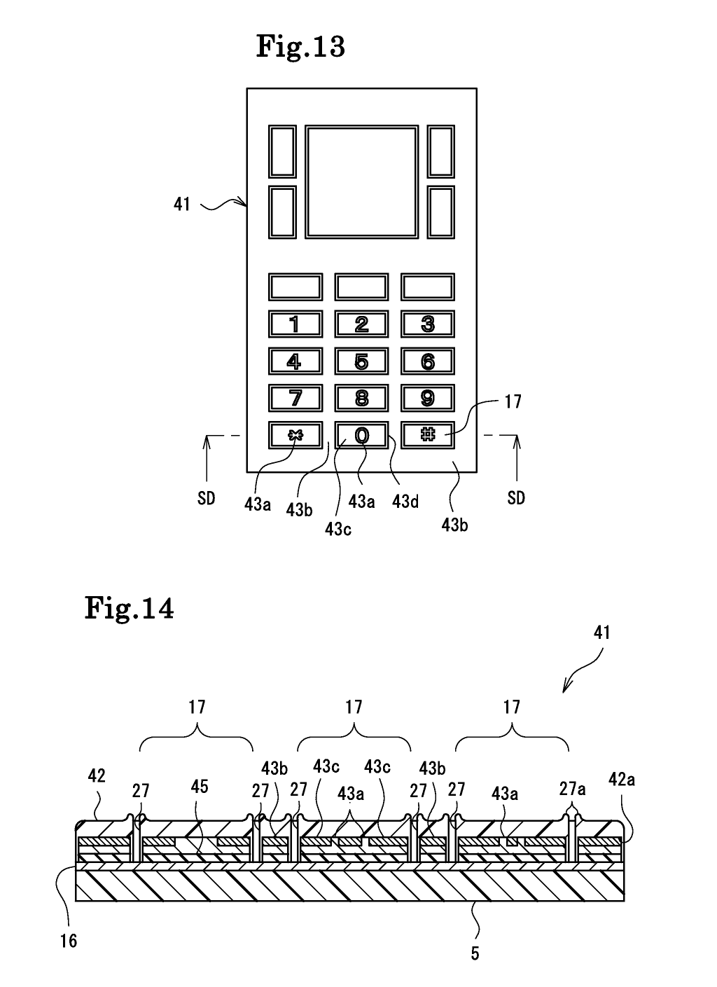

### Seventh Embodiment (FIGS. 13 and 14)

FIGS. 13 and 14 illustrate a key sheet 41 according to the seventh embodiment. FIG. 13 is a plan view of the key sheet 41, and FIG. 14 is a sectional view of the key sheet 41, which is taken along the line SD-SD. Unlike the key sheet 23 illustrated in FIG. 10, the key sheet 41 further includes a foam layer 45 as a “porous layer.” That is, in the key sheet 41, a soft-feel layer is constituted by a skin layer 42, a character layer 43, and the foam layer 45. Further, the skin layer 42 according to this embodiment has extended outer edge portions for covering side surfaces of edge portions of each of the character layer 43 and the foam layer 45.

Further, the through-holes 27 passing therethrough in the thickness direction are formed in the soft-feel layer, and constitute the partition portions 27 for partitioning the pressing-operation parts 17. In addition, on front surfaces of the partition portions 27, ends of the skin layer 42 rise so as to form bulges 27a.

The key sheet 41 is manufactured by forming the character layer 43 and the foam layer 45 through lamination on the skin layer 42, and then performing laminating on the soft-feel layer constituted by those layers and the base sheet 5 with use of the adhesive film 16. Next, by thermal-compression bonding or ultrasonic welding, a jig is pressed from the skin layer 42 side onto the sheet thus obtained so as to compress the foam layer 45 in a thickness direction in a flattening manner. Then, along with cutting of the soft-feel layer, edges of the soft-feel layer are covered with the skin layer 42 so as to form the partition portions 27. In this manner, the key sheet 41 is obtained.

According to the key sheet 41, illumination through the partition portions 27 can be performed irrespective of the translucency of the foam layer 45, and hence the pressing-operation parts 17 are visible. Further, the bulges 27a are provided on the peripheries of the partition portions 27, and hence touch feelings of the pressing-operation parts 17 can be obtained.

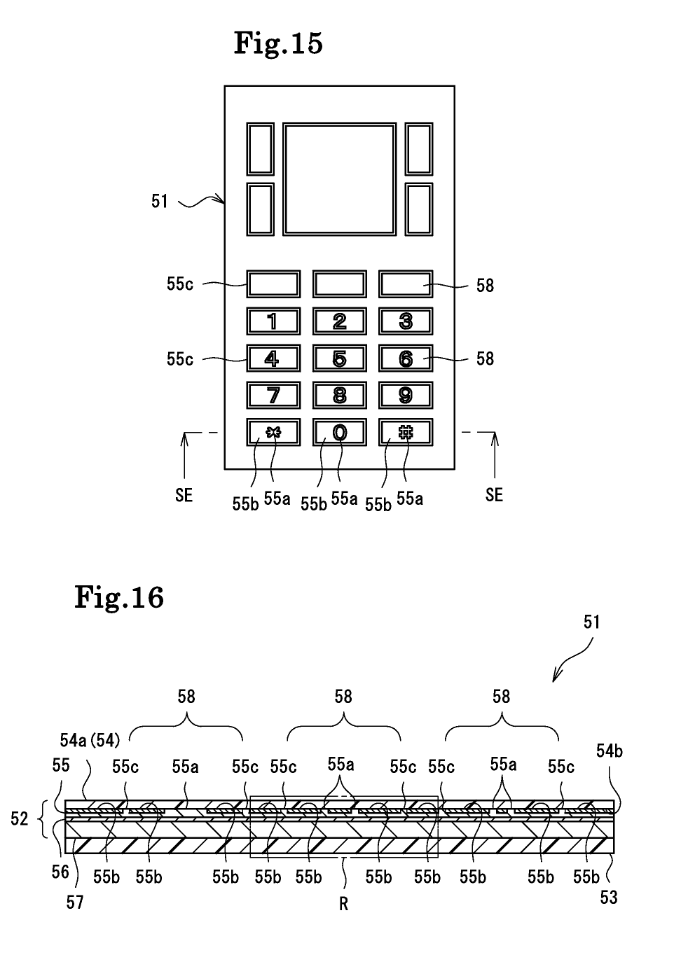

### Eighth Embodiment (FIGS. 15 to 18)

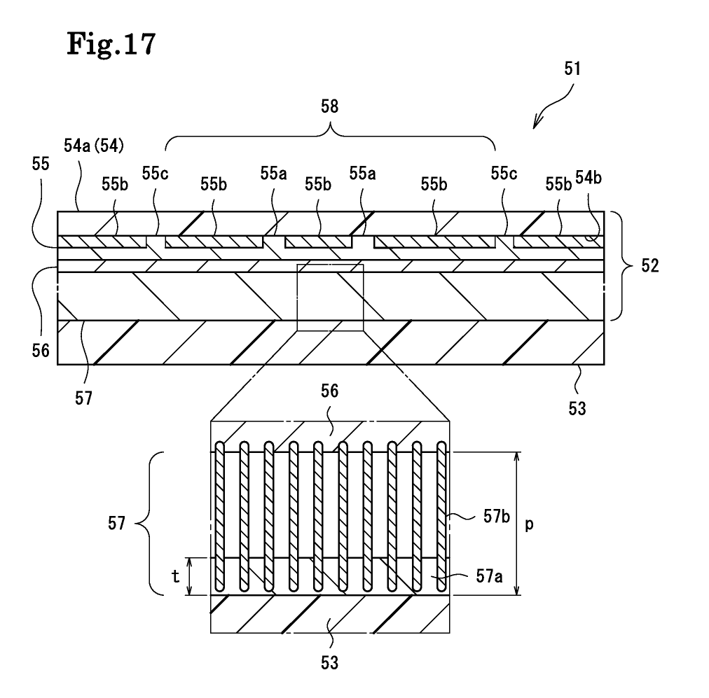

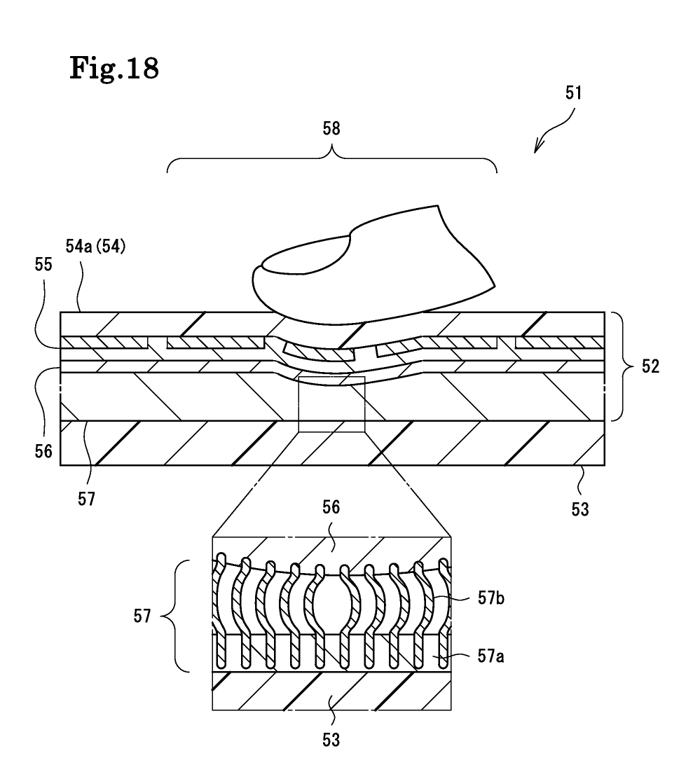

FIGS. 15 to 18 illustrate a key sheet 51 according to the eighth embodiment. FIG. 15 is a plan view of the key sheet 51, and FIG. 16 is a sectional view of the key sheet 51, which is taken along the line SE-SE. FIG. 17 is a partially enlarged sectional view of the key sheet 51, and FIG. 18 is an explanatory view of a case where a finger touches the key sheet 51.

The key sheet 51 according to the eighth embodiment includes a soft-feel layer 52 and a base sheet 53. The soft-feel layer 52 is constituted by a skin layer 54, a character layer 55, a bonding layer 56, and an hair-implanted layer 57 laminated in the stated order from an operating surface (front surface) side.

First, description is made of the layers constituting the soft-feel layer 52.

The skin layer 54 is a layer providing an outward appearance and a touch feeling as those of leather. A polymer material is formed into a sheet-like shape, and the outward appearance and the touch feeling as those of leather are provided owing to unique characteristics of the polymer material and provision of asperities on a front surface 54a.

As a material for the skin layer 54, similarly to the skin layer 2, there may be used a resin or elastomer excellent in abrasion resistance, waterproofness, and chemical resistance. Examples thereof include polyolefin-based resins such as polyethylene and polypropylene, polystyrene-based resins such as polystyrene and a styrene-maleic anhydride copolymer, polyurethane-based resins, polyvinyl chloride-based resins, and thermoplastic elastomers. Of those, excellent leather-like touch feeling can be obtained when using polyurethane-based resins.

In addition, it is possible to use resin components obtained by mixing expandable beads, hollow beads, elastic beads, inorganic materials, or the like with the resins or the elastomer. With addition of the beads and the inorganic materials, it is possible to form asperities on the skin layer 54 so as to provide various touch feelings which cannot be described in a single phrase “leather-like feeling.” The expandable beads are beads that become hollow when heated, and as a material for the expandable beads, there are exemplified polyurethane, an acrylic-urethane copolymer, polystyrene, and a styrene-isoprene copolymer. The hollow beads are a hollow spherical object, and as a material for the hollow beads, there are exemplified copolymers of vinylidene chloride and acrylonitrile and a across-linked acrylic polymer. The elastic beads are resin particles which have an elastic recovery property, when pressure is applied until a shape of the beads changes and then released. Examples thereof include polyurethane resins, acrylic-urethane resins, polystyrene resins, and a styrene-isoprene copolymer. Examples of the inorganic materials include silicon dioxide (SiO₂; also referred to as silica and silicic anhydride), hydrous silicate (SiO₂·xH₂O), and hydrous aluminum silicate (Al₂O₃9SiO₂·xH₂O). Further, a leather-like smooth touch feeling can be obtained by transferring and molding an asperity pattern onto the operating surface of the skin layer 54 with use of a jig or a die.

The above-mentioned resins or elastomer may be mixed with various additives including a colorant such as a pigment or a dye, an antioxidant, and an ultraviolet absorber.

It is preferred that a thickness of the skin layer 54 range from 5 μm to 200 μm. This is because the skin layer 2 having a thickness of less than 5 μm is liable to suffer breakage owing to its poor durability and the skin layer 2 having a thickness of more than 200 μm impairs a touch feeling with respect to the operator owing to its high rigidity, which leads to difficulty in achieving the leather-like touch feeling.

The hair-implanted layer 57 is a layer including a support layer 57a and a plurality of stringlike piles 57b, has flexibility, and provides a leather-like touch feeling synergistically with touch of the skin layer 54. Specifically, one ends of the piles 57b are implanted to the support layer 57a formed on the base sheet 53, and other ends thereof are bonded to the bonding layer 56 spaced apart from the support layer 57a. Thus, a portion corresponding to centers of the piles 57b, that is, a gap portion between the support layer 57a and the bonding layer 56 is deflectable. When the skin layer 54 is pressed, the piles 57b are deflected and the hair-implanted layer 57 is compressed in a thickness direction (FIG. 18). When being released from pressing, the deflected piles 57b return to original shapes and a thickness of the hair-implanted layer 57 is restored. In this manner, the hair-implanted layer 57 is easily flattened in the thickness direction, and hence flexibility is imparted to the soft-feel layer 52.

As a material for the support layer 57a, there may be used a reaction-curing adhesive which is elastic at the time of implanting of the piles 57b and is capable of bonding the piles 57b after implanting. In this context, examples of the reaction-curing adhesive include photo-setting adhesives and thermosetting adhesives of the following types: an acrylic one, a urethane-based one, or a vinyl-acetate-based one.

It is preferred that a layer thickness t of the support layer 57a be smaller than a length p of the piles 57b, which is described later. This is because there arises a risk that the piles 57b are buried in the support layer 56a when the layer thickness t of the support layer 57a is equal to or more than the length p of the piles 57b. Specifically, it is preferred that the layer thickness t of the support layer 57a fall within a range of p/10≦t≦9p/10. This is because, when the layer thickness t of the support layer 57a is smaller than p/10, a maximum value of the length p of the piles 57b buried in the support layer 57a is limited to p/10, which may lead to a risk that intervals between the piles 57b are increased and the piles 57b are superimposed on each other. Meanwhile, when the layer thickness t of the support layer 57a is more than 9p/10, the length of the piles 57b protruding from the support layer 57a is small, with the result that the soft touch feeling cannot be obtained from the hair-implanted layer 57.

The piles 57b are formed by extending from an implanted part in a string form, and natural fibers or artificial fibers may be used as a raw material therefor. Examples of the fibers include cotton, silk, rayon, polyamide-based fibers, polyester-based fibers, polyurethane-based fibers, polypropylene (polyproylene)-based fibers, and polyvinyl chloride-based fibers.

It is preferred that the length of the piles 57b range from 0.1 mm to 2.0 mm. This is because the piles 57b having a length of less than 0.1 mm is less liable to deflect, and hence the hair-implanted layer is less liable to deflect. Meanwhile, the piles 57b having a length of more than 2.0 mm causes the skin layer to be thicker, with the result that a thin key sheet cannot be obtained. It is preferred that a thickness of the piles 57b range from 0.1 D to 5.0 D. Strength of the piles 57b having a thickness of less than 0.1 D is low, which may lead to a risk in that the piles compressed through pressing are difficult to restore when being released from pressing. Meanwhile, strength of the piles 57b having a thickness of more than 5.0 D is excessively high, which may lead to a risk in that a soft touch feeling cannot be obtained.

In order to obtain a key sheet excellent in illuminating properties, it is preferred that a translucent material be used for the support layer 57a.

The character layer 55 is a layer for rendering display elements such as letters, numerals, and symbols. In this embodiment, the character layer 55 is formed as an application layer printed on a back surface 54b of the skin layer 54. The character layer 55 is constituted by display portions 55a for indicating the display elements such as letters, numerals, and symbols, background portions 55b forming peripheries of the display portions 55a, and rectangularly-annular partition lines 55c for defining pressing-operation parts 58.

That is, in the character layer 55, a first application layer is provided with respect to the back surface 54b of the skin layer 54 so as to form the background portions 55b. In addition, a second application layer covering the first application layer is provided on the entire back surface 54b of the skin layer 54 so as to define the display portions 55a and the partition lines 55c.

When both the first and second application layers are translucent, backlight is allowed to transmit therethrough. When light transmittance of the first application layer is set to be lower than light transmittance of the second application layer, the light transmittance of the display portions 55a and the partition lines 55c is higher than the light transmittance of the background portions 55b. As a result, the display portions 55a and the partition lines 55c can be illuminated more brightly than the background portions 55b.

The bonding layer 56 is a layer for bonding the hair-implanted layer 57 to a back surface of the character layer 55. That is, the bonding layer bonds the other ends of the piles 57b.

As a material for the bonding layer 56, there may be provided a reaction-curing adhesive capable of bonding the piles 57b. In this context, examples of the reaction-curing adhesive include photo-setting adhesives and thermosetting adhesives of the following types: an acrylic one, a urethane-based one, or a vinyl-acetate-based one. Note that, when the character layer 55 has a property of exhibiting adhesiveness after being molded through application as in a case of a hot-melt adhesive, the bonding layer 56 may be omitted.

In order to obtain a key sheet excellent in illuminating properties, it is preferred that a translucent material be used for the bonding layer 56.

Next, description is made of the base sheet 53. The base sheet 53 has a function of providing formability of the key sheet 51.

As the material for the base sheet 53, similarly to the base sheet 5, thermoplastic resins or thermosetting resins may be used. Examples thereof include an acrylic resin, a styrene resin, a polyester resin, a polyolefin resin, a silicone resin, an epoxy resin, and a urethane resin. It is preferred that a thickness of the base sheet 3 as described above range from 100 μm to 500 μm. This is because the base sheet 51 having a thickness of less than 100 μm may suffer breakage in post-processing owing to its poor strength, and has difficulty in maintaining a shape of the key sheet 51 owing to its poor rigidity. The base sheet 51 having a thickness of more than 500 μm is difficult to deflect owing to its high rigidity, which leads to an increase in pressing load so as to deteriorate operability in a case of a key sheet for an operation by pressing input.

In order to obtain a key sheet excellent in illuminating properties, it is preferred that a translucent material be used for the base sheet 53.

Description is made of the manufacturing method for the key sheet 51.

First, the character layer 55 is molded through application on the back surface 54b of the skin layer 54. Meanwhile, the hair-implanted layer 57 is formed with respect to a front surface 53a of the base sheet 53. Specific description thereof is made later. Next, the bonding layer 56 is applied on the back surface of the character layer 55 and is opposed to the hair-implanted layer 57. After that, the piles 57b of the hair-implanted layer 57 is bonded to the bonding layer 56 through laminating. In this manner, the key sheet 51 is obtained.

The hair-implanted layer 57 is formed as follows.

First, the support layer 57a is coated on the front surface 53a of the base sheet 53. As a coating method, there may be adopted splay coating, screen printing, gravure printing, and transferring. Next, the plurality of piles 57b are implanted by being caused to electrostatically adhere to the support layer 57a provided to the front surface 53a of the base sheet 53. Lastly, the support layer 57a is cured. In this manner, it is possible to form the hair-implanted layer 57 in which the plurality of piles 57b are implanted to the front surface 53a of the base sheet 53. Note that, electrostatic hair-implantation as described above is effected on the base sheet 53, and hence it is possible to perform successive formation of the key sheet 51, which facilitates manufacture of the key sheets.

Instead of the electrostatic hair-implantation method, it is also possible to form the hair-implanted layer 57 by a solvent-dispersing method or air-pressure forming. In the solvent-dispersing method, a paint is applied to the base sheet 53, and the piles 57b dispersed in the solvent are sprayed onto the paint prior to curing thereof. Surplus piles are removed after drying and curing those. In this manner, the hair-implanted layer 57 can be formed. In the air-pressure forming, the piles 57b are supplied in the air while being dispersed and diffused in the air-pressure state, and then bonded by being uniformly dispersed in random directions with respect to the bonding layer provided to the front surface 53a of the base sheet 53. In this manner, the hair-implanted layer 57 can be formed.

Next, description is made of actions and effects of the key sheet 51 according to this embodiment.

According to the key sheet 51, an outward appearance and a touch feeling as those of leather are provided owing to the skin layer 54 on the operating surface, and a more realistic leather-like soft touch feeling is provided owing to the hair-implanted layer 57. In this manner, it is possible to realize a key sheet 51 which provides a leather-like touch feeling. The character layer 55 forming display elements is provided between the skin layer 54 and the hair-implanted layer 57, and hence it is possible to enhance visibility of the display elements.

Further, in the hair-implanted layer 57, light transmits between the piles 57b implanted in a direction crossing a plane direction of the base sheet 53, and hence the light transmitting through between the piles 57b is less liable to be blocked. As a result, the key sheet 51 constituted by the translucent base sheet 53, the translucent hair-implanted layer 57, the translucent bonding layer 56, and the translucent skin layer 54 enables backlight illumination. Thus, it is possible to realize a key sheet 51 excellent in visibility, which can be illuminated through the display portions 55a even in a dark place.

The piles 57b is directly implanted with respect to the support layer 57a formed on the base sheet 53, and hence it is unnecessary to provide a pile sheet as a separate member. Thus, it is possible to realize a thin key sheet 51. Further, with the provision of the piles 57b, the key sheet 51 is durable for repetitive use and excellent in durability.

The character layer 55 is provided on the back surface of the skin layer 54, and hence the fingers of an operator come into direct touch with the skin layer 54 at the time of a pressing operation. Thus, a leather-like soft touch feeling can be reliably obtained as a touch feeling. Further, it is possible to prevent abrasion of the character layer 55, and hence the display portions 55a are accurately visible. Still further, only the skin layer 54 is formed on the front surface side, and hence the display portions 55a are clearly visible through the skin layer 54. In addition, in comparison with related arts in which display elements formed of clipped portions are provided in a pressing operation portion, according to the present invention in which the display portions 55a formed of the character layer 55 are provided, it is possible to realize a key sheet 51 which is less liable to abrade and excellent in durability. Further, the rectangularly-annular partition lines 55c are provided for surrounding the pressing-operation parts 58, and hence it is possible to cause the pressing-operation parts 58 to be more visible and possible to prevent misinputs.

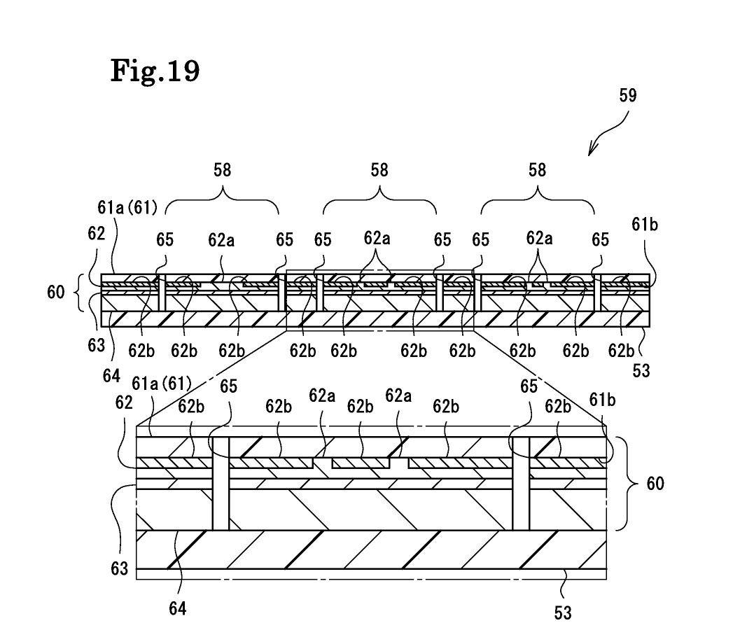

### Ninth Embodiment (FIG. 19)

FIG. 19 illustrates a key sheet 59 according to the ninth embodiment. FIG. 19 is a sectional view of the key sheet 59. The key sheet 59 according to the ninth embodiment is different from the key sheet 51 according to the eighth embodiment in that there are formed through-holes 65 passing through a soft-feel layer 60 in a thickness direction thereof and “partition lines” for partitioning the pressing-operation parts 58. Similarly to the soft-feel layer 52 in the eighth embodiment, the soft-feel layer 60 in this embodiment is constituted by a skin layer 61, a character layer 62, a bonding layer 63, and a hair-implanted layer 64 laminated in the stated order from an operating surface (front surface) side.

Similarly to the key sheet 51 according to the eighth embodiment, the key sheet 59 is manufactured by forming the soft-feel layer 60 not provided with the through-holes 65. Lastly, a blade is applied from above the skin layer 61 so as to form the through-holes 65 passing through the skin layer 61, the character layer 62, the bonding layer 63, and the hair-implanted layer 64. In this manner, the key sheet 59 is obtained.

In the key sheet 59, the soft-feel layer 60 includes the through-holes 65 as the partition lines for partitioning the pressing-operation parts 58. Thus, when the base sheet 53 is translucent, backlight is allowed to illuminate the key sheet 59 through the base sheet 53 and the through-holes 65. As a result, it is possible to differentiate brightness of light transmitting through display portions 62a and background portions 62b and brightness of light transmitting through the through-holes 65 from each other. As a result, it is possible to realize a key sheet 59 with characteristic illumination properties.

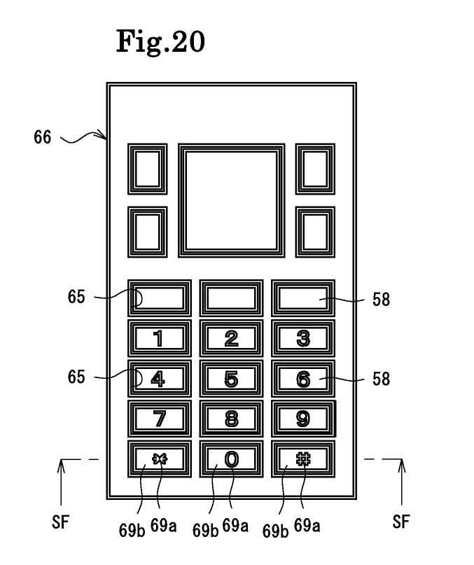

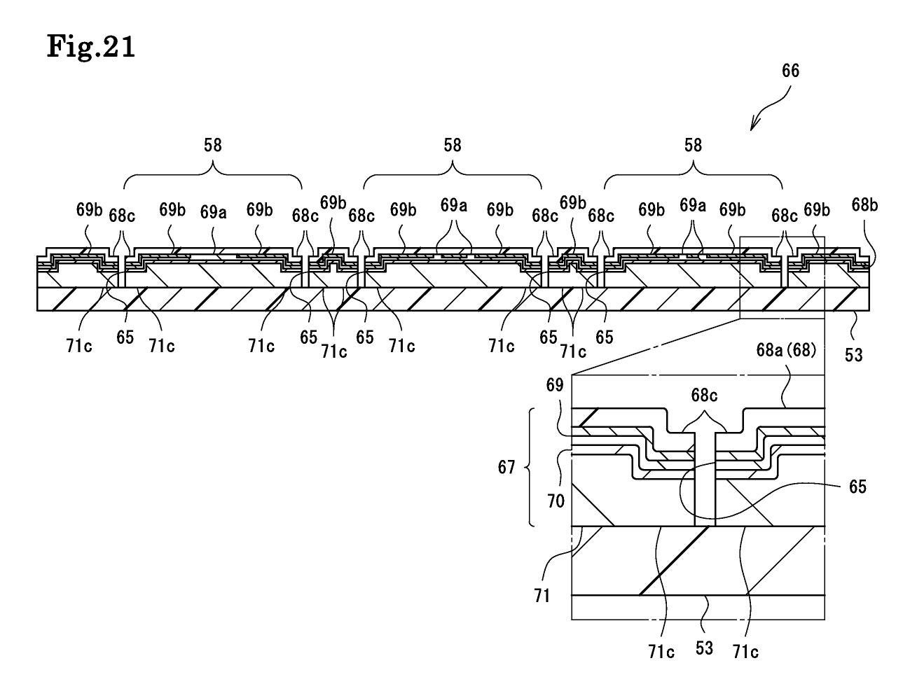

### Tenth Embodiment (FIGS. 20 and 21)

FIGS. 20 and 21 illustrate a key sheet 66 according to the tenth embodiment. FIG. 20 is a plan view of the key sheet 66, and FIG. 21 is a sectional view of the key sheet 66, which is taken along the line SF-SF. The key sheet 66 according to the tenth embodiment is different from the key sheet 59 according to the ninth embodiment in that compressed portions 71c formed by compressing a hair-implanted layer 71 are formed at edge portions of a skin layer 68 so as to provide stepped surfaces 68c. Similarly to the soft-feel layer 52 in the first embodiment, a soft-feel layer 67 in this embodiment is constituted by the skin layer 68, a character layer 69, a bonding layer 70, and the hair-implanted layer 71 laminated in the stated order from an operating surface (front surface) side.

The hair-implanted layer 71 in this embodiment is provided with the compressed portions 71c flattened at the edge portions in a thickness direction thereof. A material for the piles in this embodiment is a thermoplastic resin. The thermoplastic resin is easily deformed or molten by ultrasonic welding or thermal-compression bonding in a pressurized state, and hence the support layer and the bonding layer 70 are brought into close contact with each other. As a result, a solid layer is formed.

Further, the rectangularly-annular through-holes 65 as “partition lines” for partitioning the pressing-operation parts 58 pass through the skin layer 68, the character layer 69, the bonding layer 70, and the hair-implanted layer 71 in the thickness direction thereof. As described above, in the key sheet 66, the edge portions of the soft-feel layer 67 are flattened in the thickness direction.

Similarly to the key sheet 51 according to the eighth embodiment, the key sheet 66 is manufactured by forming the soft-feel layer 67 not provided with the through-holes 65, and after that, compressing the soft-feel layer 69 by thermal-compression bonding or ultrasonic welding from the skin layer 68 side so as to form the stepped surfaces 68c on the skin layer 68 through flattening the hair-implanted layer 71. Lastly, a blade is applied from above the skin layer 68 to bottom surfaces of the stepped surfaces 68c so as to form the through-holes 65 passing through the skin layer 68, the character layer 69, the bonding layer 70, and the hair-implanted layer 71. In this manner, the key sheet 66 is obtained.

According to the key sheet 66, with the provision of the compressed portions 71c at the edge portions of the hair-implanted layer 71, it is possible to prevent the compressed portions 71c from wearing off unlike uncompressed hair-implanted layers even when being abraded, and from being eroded by chemicals. Thus, the edge portions of the hair-implanted layer 71 are prevented from suffering breakage even during use, and hence it is possible to enhance durability thereof.

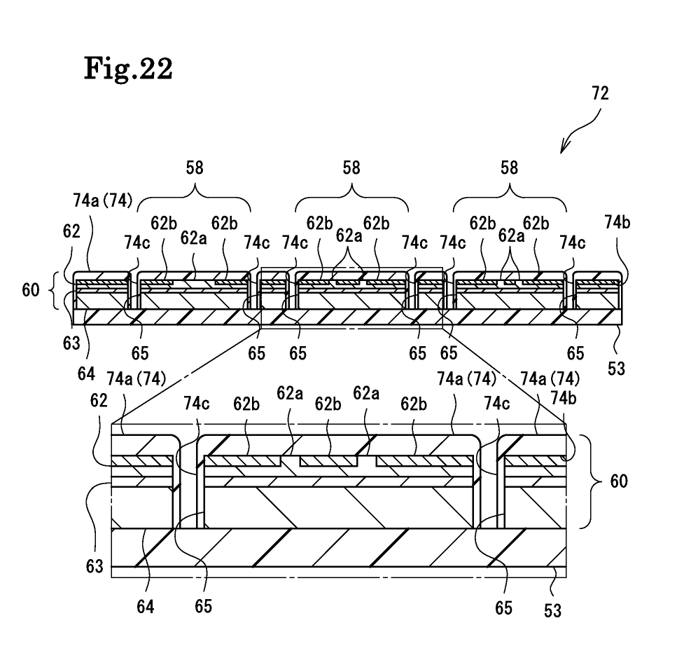

### Eleventh Embodiment (FIG. 22)

FIG. 22 illustrates a key sheet 72 according to an eleventh embodiment. FIG. 22 is a sectional view of the key sheet 72. While including the through-holes 65 similarly to the key sheet 59 according to the ninth embodiment, the key sheet 72 according to the eleventh embodiment is different from the key sheet 59 according to the ninth embodiment in that edge portions of a skin layer 74 extend so as to form protective portions 74c for covering a side surface of an edge portion of each of the character layer 62, the bonding layer 63, and the hair-implanted layer 64. Similarly to the soft-feel layer 52 in the eighth embodiment, a soft-feel layer 73 in this embodiment is constituted by the skin layer 74, the character layer 62, the bonding layer 63, and the hair-implanted layer 64 laminated in the stated order from an operating surface (front surface) side.

Similarly to the key sheet 59 according to the ninth embodiment, the key sheet 72 is manufactured by forming the soft-feel layer 73 not provided with the through-holes 65, and after that, by pressing the soft-feel layer 73 by thermal-compression bonding or ultrasonic welding from the skin layer 74 side so as to compress the hair-implanted layer 64 in a thickness direction in a flattening manner. Then, along with cutting of the character layer 62, the bonding layer 63, and the hair-implanted layer 64, the edges of the character layer 62, the bonding layer 63, and the hair-implanted layer 64 are covered with the protective portions 74c of the skin layer 74 so as to form the through-holes 65. In this manner, the key sheet 72 is obtained.

In the key sheet 72, the protective portions 74c are provided for covering the side surfaces of the edge portions of the hair-implanted layer 64 so as not to expose the hair-implanted layer 64 to the outside. Thus, it is possible to enhance durability of the hair-implanted layer 64.

In the following, description is made on modifications common to the eighth to eleventh embodiments. Note that, while description is representatively made on modifications of the key sheet 51 according to the eighth embodiment, characteristic structure of the following modifications is also applicable to the respective key sheets 59, 66, and 72 according to the ninth to eleventh embodiments.

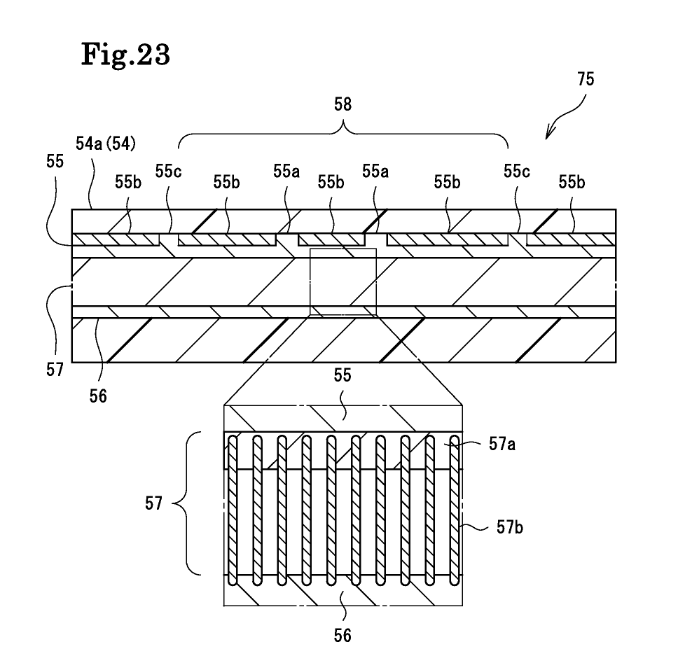

### First Modification of Eighth Embodiment (FIG. 23)

FIG. 23 is a sectional view of a key sheet 75 of a first modification. A mode of the hair-implanted layer is changed in the key sheet 75. That is, in the key sheet 75, the support layer 57a is provided on the back surface of the character layer 55, and the base sheet 53 and the hair-implanted layer 57 are bonded to each other with the bonding layer 56. In comparison with the key sheet 51 according to the eighth embodiment, the position of the support layer in the hair-implanted layer is upside down.

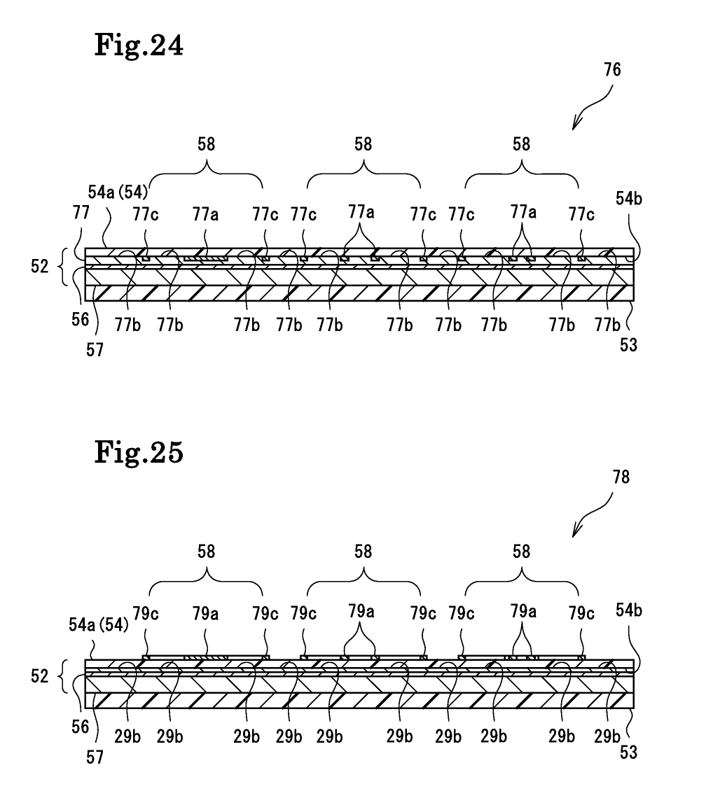

### Second Modification of Eighth Embodiment (FIG. 24)

FIG. 24 is a sectional view of a key sheet 76 of a second modification. A mode of the character layer is changed in the key sheet 76. That is, in the key sheet 76, display portions 77a and partition lines 77c are formed of a first application layer and background portions 77b are formed of a second application layer. With this, display elements are provided like protruding letters. In this regard, the key sheet 76 of the second modification is different from the key sheet 51 according to the eighth embodiment, in which the background portions 55b are formed of the first application layer and the display portions 55a and the partition lines 55c are formed of the second application layer. With this, it is possible to set light transmittance of the display portions 77a and the partition lines 77c to be lower than light transmittance of the background portions 77b. Thus, the background portions 77b can be illuminated with backlight more brightly than the display portions 77a and the partition lines 77c.

### Third Modification of Eighth Embodiment (FIG. 25)

FIG. 25 is a sectional view of a key sheet 78 of a third modification. The mode of the character layer is changed also in the key sheet 78. The key sheet 78 has a character layer 79 in which a first application layer forming display portions 79a and partition lines 79c is formed on the front surface 54a of the skin layer 54 and a second application layer forming background portions 79b is formed on the back surface 54b of the skin layer 54. In this regard, the key sheet 78 of the third modification is different from the key sheet 51 according to the eighth embodiment, in which the character layer 55 constituted by the first and second application layers is provided on the back surface 54b of the skin layer 54.

The first application layer and the second application layer are separably provided on the front surface and the back surface of the skin layer 54, respectively. With this, it is possible to form display elements with three-dimensionality.

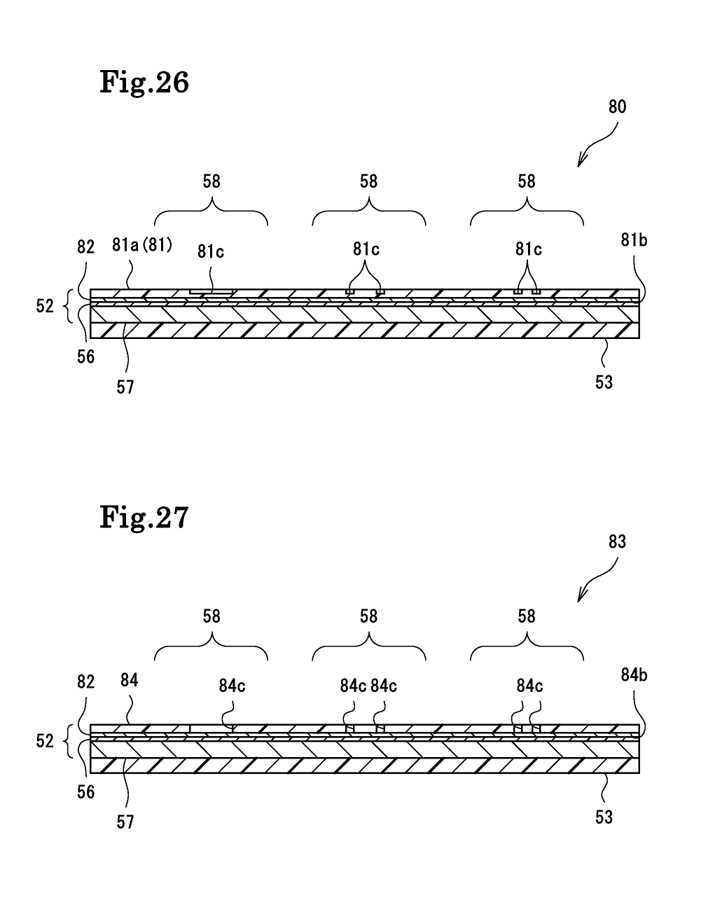

### Fourth Modification of Eighth Embodiment (FIG. 26)

FIG. 26 is a sectional view of a key sheet 80 of a fourth modification. The mode of the character layer is changed also in the key sheet 80. In the key sheet 80, display recessed portions 81c forming display portion (display elements) are formed by providing recessed portions in a front surface 81a of a skin layer 81, and a background portion is formed by providing an application layer 82 on a back surface 81b of the skin layer 81. In this regard, the key sheet 80 of the fourth modification is different from the key sheet 51 according to the eighth embodiment, in which the character layer 55 constituted by the first and second application layers is provided on the back surface 54b of the skin layer 54. With this, the display elements can be confirmed with touch feelings to the fingers. Note that, instead of the formation with the application layer 82, the background portions may be formed of the bonding layer 56.

### Fifth Modification of Eighth Embodiment (FIG. 27)

FIG. 27 is a sectional view of a key sheet 83 of a fifth modification. The mode of the display layer is changed in the key sheet 83, and display elements are formed. In the key sheet 83, display holes 84c forming display portion (display elements) are provided in the skin layer 84 while passing through the thickness thereof, and the application layer 82 forming the background portion is provided on a back surface 84b of the skin layer 84. In this regard, the key sheet 83 of the fifth modification is different from the key sheet 51 according to the eighth embodiment, in which the character layer 55 constituted by the first and second application layers is provided on the back surface 54b of the skin layer 54. With this, the display elements can be confirmed with touch feelings to the fingers. Note that, instead of the formation with the application layer 82, the background portions may be formed of the bonding layer 56.

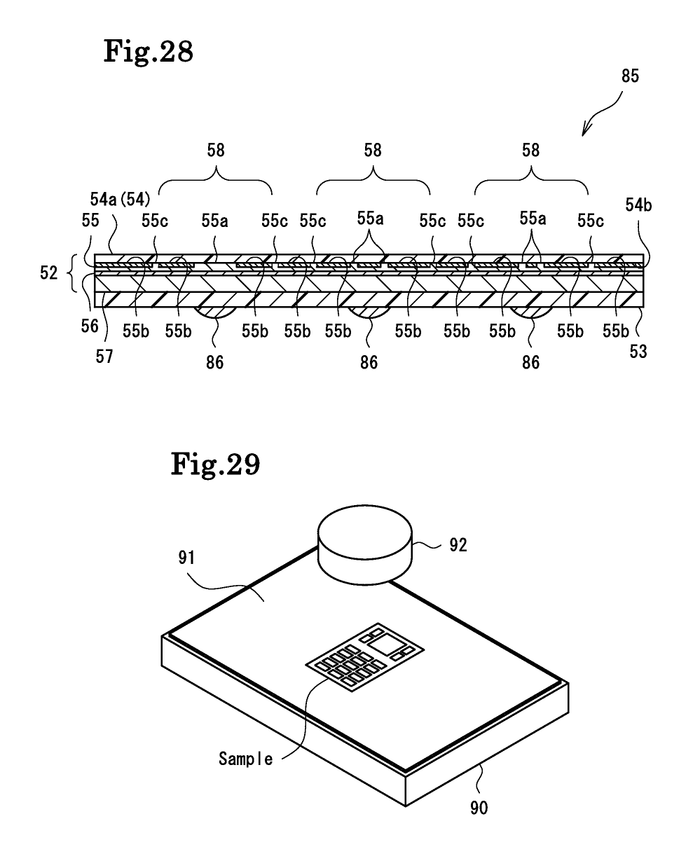

### Sixth Modification of Eighth Embodiment (FIG. 28)

FIG. 28 is a sectional view of a key sheet 85 of a sixth modification. In the key sheet 85, on a back surface 53b of the base sheet 53 of the pressing-operation parts 58, there are formed pressers 86 protruding from the back surface 53b in a pressing direction. In this regard, the key sheet 85 of the sixth modification is different from the key sheet 51 according to the eighth embodiment, in which the back surface 53b of the base sheet 53 thereof is flat. When a circuit board including disk-spring contacts is provided on a back surface of the key sheet 85, the pressers 86 are allowed to accurately press the disk-spring contacts with the provision of the pressers 86 as described above. As a result, it is possible to realize a reliable pressing operation.

### Twelfth Embodiment (FIGS. 31 to 33)

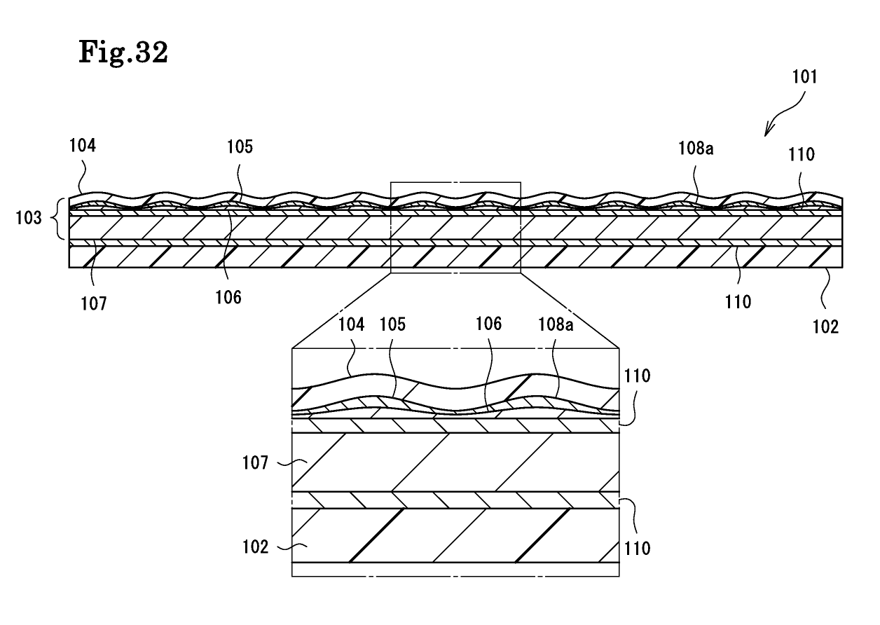

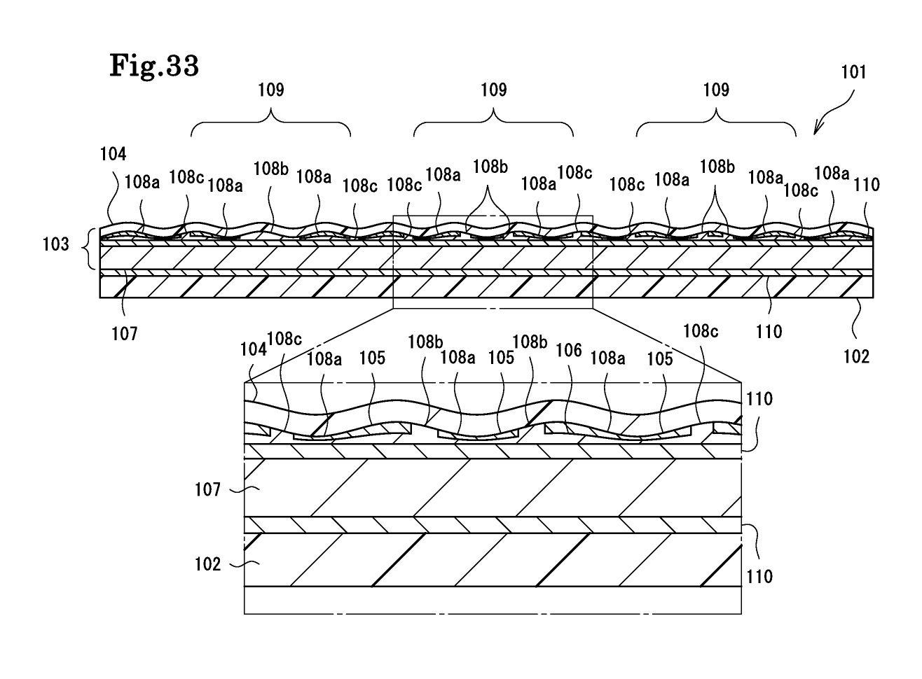

FIGS. 31 to 33 illustrate a key sheet 101 according to a twelfth embodiment. FIG. 31 is a plan view of the key sheet 101, FIG. 32 is a sectional view of the key sheet 101, which is taken along the line SG-SG, and FIG. 33 is a sectional view of the key sheet 101, which is taken along the line SH-SH. The key sheet 101 according to the twelfth embodiment includes a base sheet 102 and a soft-feel layer 103. The soft-feel layer 103 is constituted by a skin layer 104, a first decorative layer 105, a second decorative layer 106, and a porous layer 107 as an “elastic layer” laminated in the stated order from an operating surface (front surface) side.

The skin layer 104 is an outermost layer providing a soft touch feeling, and is formed of a translucent polymer material to be formed into a sheet-like shape. A front surface and a back surface of the skin layer 104 are formed in an asperity shape constituted by inclined surfaces, the asperity shape being formed in a grid pattern in plan view. It is preferred that a depth of recessed portions in the asperity shape range from 5 μm to 500 μm. This is because the pattern of the asperity shape is less visible when the recessed portions have a depth of less than 5 μm. In addition, the first decorative layer is formed as a substantially flat layer, and hence it is difficult to visualize change in hue of the first decorative layer. Further, it is difficult to form the first decorative layer with respect to the recessed portion in the asperity shape when the recessed portions have a depth of more than 500 μm.

As a material for the skin layer 104, there may be used a resin or elastomer excellent in abrasion resistance, waterproofness, and chemical resistance. Examples thereof include polyolefin-based resins such as polyethylene and polypropylene, polystyrene-based resins such as polystyrene and a styrene-maleic anhydride copolymer, polyurethane-based resins, polyvinyl chloride-based resins, and thermoplastic elastomers. Of those, excellent leather-like touch feeling can be obtained when using polyurethane-based resins. Those resins or elastomer may be mixed with various additives including a colorant such as a pigment or a dye, an antioxidant, and an ultraviolet absorber. The material for the skin layer 104 may be the same as that for the skin layer 2.

It is preferred that a thickness of the skin layer 104 as described above range from 5 μm to 200 μm. This is because the skin layer 2 having a thickness of less than 5 μm is liable to suffer breakage owing to its poor durability and the skin layer 2 having a thickness of more than 200 μm impairs a touch feeling with respect to the operator owing to its high rigidity, which leads to difficulty in achieving the leather-like touch feeling.

The first decorative layer 105 is a layer for mainly decorating the key sheet 101 formed by printing on the back surface of the skin layer 104, and forms background portions 108a forming peripheries of display elements such as letters, numerals, and symbols. That is, the first decorative layer 105 is formed while forming the following in a hole-forming manner: display portions 108b indicating the display elements and partition lines 108c surrounding pressing-operation parts 109 (FIG. 33). In addition, the first decorative layer 105 is formed in a non-uniform layer thickness on the back surface of the skin layer 104. In other words, a film thickness of the first decorative layer 105 is larger near bottoms of the recessed portions of the skin layer 104, becomes gradually smaller from the recessed portions to protruding portions, and is smallest over the protruding portions. A back surface of the first decorative layer 105 as described above is formed in an asperity shape.

As a material for the first decorative layer 105, there may be provided an ink and a paint applicable to the skin layer 104, and a metal capable of being subjected to dry plating. Note that, when the first decorative layer 105 is translucent, the display elements can be illuminated brightly in a case of adopting backlight illumination.

The second decorative layer 106 is a layer for complementarily decorating the key sheet 101 formed by printing on a back surface of the first decorative layer 105, and fills holes of the first decorative layer 105 so as to form the display portions 108b and the partition lines 108c. In addition, the second decorative layer 106 is provided with a color different from that of the first decorative layer 105. Note that, instead of being formed as a flat surface as in the figure, a back surface of the second decorative layer 106 may be formed as an asperity surface. Description is made later of a modification in which the back surface of the second decorative layer is formed as an asperity surface as described above.

As a material for the second decorative layer 106, there may be provided an ink and a paint applicable to the base sheet 102, and a metal capable of being subjected to dry plating. Note that, when the second decorative layer 106 has a property of exhibiting adhesiveness after being molded through application as in a case of a hot-melt adhesive, the porous layer 107 and bonding layers 110 bonded thereto may be omitted. Further, when the second decorative layer 106 is translucent, the display elements can be illuminated brightly in a case of adopting backlight illumination.

The porous layer 107 is an easily-depressed layer laminated on the back surface side of the second decorative layer 106, and is formed of a foamed body with low compression elasticity. A front surface of the porous layer 107 is bonded to the back surface of the second decorative layer 106 with one of the bonding layer 110, and a back surface thereof is bonded to a front surface of the base sheet 102 with another of the bonding layer 110.

A material for the porous layer 107 is a resin or an elastomer which may be formed into a foam, and similarly to the material for the skin layer 104, as a material therefor, there are exemplified polyolefin-based resins such as polyethylene and polypropylene, polystyrene-based resins such as a polystyrene and styrene-maleic anhydride copolymer, polyurethane-based resins, polyvinyl chloride-based resins, and thermoplastic elastomers. Note that the translucency of the porous layer 107 can be enhanced by reducing a thickness thereof or lowering a degree of foaming.

The base sheet 102 has a function of providing formability of the key sheet 101, and is formed of a translucent resin. Note that, with provision of pressers on a back surface of the base sheet 102, it is possible to enhance pressing operability.

As the material for the base sheet 102, thermoplastic resins or thermosetting resins may be used. Examples thereof include an acrylic resin, a styrene resin, a polyester resin, a polyolefin resin, a silicone resin, an epoxy resin, and a urethane resin. The material for the base sheet 102 as described above may be the same as that of the base sheet 5. It is preferred that a thickness of the base sheet 102 range from 100 μm to 500 μm. This is because the base sheet 51 having a thickness of less than 100 μm may suffer breakage in post-processing owing to its poor strength, and has difficulty in maintaining a shape of the key sheet 101 owing to its poor rigidity. The base sheet 51 having a thickness of more than 500 μm is difficult to deflect owing to its high rigidity, which leads to an increase in pressing load so as to deteriorate operability in a case of a key sheet for an operation by pressing input.

The bonding layers 110 are formed of an adhesive or a pressure-sensitive adhesive. Examples of the usable adhesives include an adhesive film, a pressure-sensitive adhesive film, and a hot-melt adhesive.

Next, description is made of a manufacturing method for the key sheet 101.

First, the asperity shape is transferred and molded onto the front and back surfaces of the skin layer 104 with use of a mold-release sheet or a die. Next, the first decorative layer 105 is formed by printing on the back surface of the skin layer 104, and further, the second decorative layer 106 is formed by printing on the first decorative layer 105. Lastly, the back surface of the second decorative layer 106 and the front surface of the porous layer 107, and a back surface of the porous layer 107 and the front surface of the base sheet 102 are bonded to each other with the bonding layers 110, respectively. In this manner, the key sheet 101 is manufactured.

In the key sheet 101, the operating surface is constituted by the skin layer 104 of the soft-feel layer 103, and the porous layer 107 is formed on the back surface side of the skin layer 104. Thus, with a combination of the skin layer 104 providing a soft touch feeling and the porous layer 107 slightly depressed at the time of a pressing operation, it is possible to realize a key sheet 101 with a soft touch feeling.

In addition, the layer thickness of the first decorative layer 105 is larger near the bottoms of the recessed portions of the skin layer 104 and becomes gradually smaller toward the protruding portions. Thus, it is possible to emphasize the color tone of the first decorative layer 105 near the bottoms of the recessed portions, and possible to weaken the color tone of the first decorative layer 105 near the protruding portions. The second decorative layer 106 having a color different from that of the first decorative layer 105 is formed on the back surface of the first decorative layer 105 as described above. Thus, the color tone of the first decorative layer 105 is emphasized near the bottoms of the recessed portions, and the color tone of the second decorative layer 106 emerges from the back side of the first decorative layer 105 whose color tone is weak near the protruding portions, and is emphasized near the protruding portions. Thus, it is possible to realize a key sheet 101 with an outward appearance of a hue which provides three-dimensionality and in which the color tone of the first decorative layer 105 is gradually changed into the color tone of the second decorative layer 106.

### Modifications of Twelfth Embodiment

It is possible to modify the skin layer 104 and the first decorative layer 105 of the key sheet 101 according to the twelfth embodiment as in the following description. Note that, those modifications are applicable as in this embodiment to the thirteenth to seventeenth embodiments specifically described later.

Modification of skin layer 104: The case is exemplified where the asperity shape of the skin layer 104 is formed in a grid pattern in plan view in the key sheet 101 according to the twelfth embodiment. Meanwhile, the asperity shape may be formed in a stripe pattern in plan view. With this, the skin layer may be provided with outward appearances of textures, such as those of denim and corduroy. For example, when a blue first decorative layer and a white second decorative layer are formed on a back surface of a skin layer having a stripe pattern in plan view, it is possible to realize a blue-jean-like outward appearance. In addition, it is possible to realize outward appearances as those of leather and woodgrain through modification of the pattern of the asperity shape, and hence possible to perform designing not only on the pattern but also on materials.

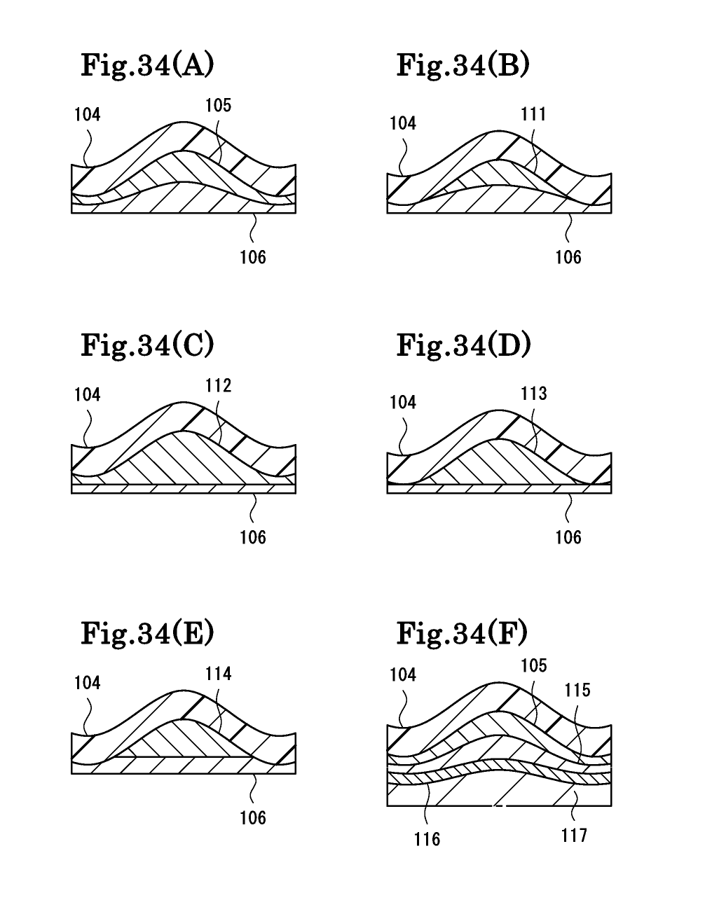

Modification of first decorative layer 105 (FIGS. 34(B) to 34(E)): The case is exemplified where, in the key sheet 101 according to the twelfth embodiment, as illustrated in FIG. 34(A), the first decorative layer 105 is formed over the entire back surface of the skin layer 104, the film thickness thereof being larger near the bottoms of the recessed portions of the skin layer 104, becoming gradually smaller toward the protruding portions, and being smallest over the protruding portions, the back surface thereof being formed as an asperity surface. Meanwhile, the first decorative layer may be modified as in the following description.

First modification of first decorative layer (FIG. 34(B)): As illustrated in FIG. 34(B), a first decorative layer 111 of the first modification is formed in the recessed portions of the skin layer 104. In this context, it is possible to form the first decorative layer 111 to have a film thickness larger near the bottoms of the recessed portions of the skin layer 104 and gradually smaller toward the protruding portions of the skin layer 104, and possible to form the back surface thereof as a recessed surface.

Second modification of first decorative layer (FIG. 34(C)): As illustrated in FIG. 34(C), a first decorative layer 112 of the second modification is formed over the entire back surface of the skin layer 104. In this context, it is possible to form the first decorative layer 112 to have a film thickness larger near the bottoms of the recessed portions of the skin layer 104 and gradually smaller toward the protruding portions of the skin layer 104 to be smallest at portions covering the protruding portions, and possible to form the back surface thereof as a flat surface.

Third modification of first decorative layer (FIG. 34(D)): As illustrated in FIG. 34(D), a first decorative layer 113 of the third modification is formed in the recessed portions of the skin layer 104. In this context, it is possible to form the first decorative layer 113 to have a film thickness larger near the bottoms of the recessed portions of the skin layer 104 and gradually smaller toward the protruding portions of the skin layer 104, and possible to form the back surface thereof as a flat surface.

Fourth modification of first decorative layer (FIG. 34(E)): As illustrated in FIG. 34(E), a first decorative layer 114 of the third modification is formed in the recessed portions of the skin layer 104. In this context, it is possible to form the first decorative layer 114 to have a film thickness larger near the bottoms of the recessed portions of the skin layer 104 and gradually smaller toward the protruding portions of the skin layer 104, and possible to form the back surface thereof as a flat surface.

Modification of second decorative layer 106 (FIG. 34(F)): The case is exemplified where the back surface of the second decorative layer 106 is formed as a flat surface in the key sheet 101 according to the twelfth embodiment. Meanwhile, as illustrated in FIG. 34(F), a back surface of a second decorative layer 115 of this modification may be formed as an asperity surface. In this modification, the first decorative layer 105 and the second decorative layer 115 are formed to be thin, and front and back surfaces of a bonding layer 116 and a front surface of a porous layer 117 are also formed as asperity surfaces. With this, it is possible to thin a soft-feel layer, and hence possible to realize a thin key sheet.

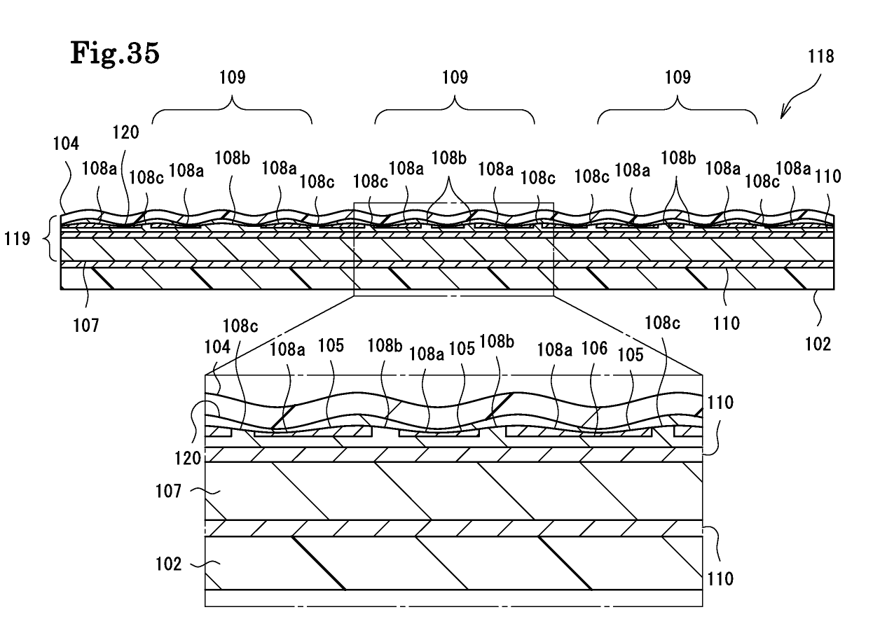

### Thirteenth Embodiment (FIG. 35)

FIG. 35 illustrates a key sheet 118 according to the thirteenth embodiment. FIG. 35 is a sectional view of the key sheet 118. The key sheet 118 according to the thirteenth embodiment is different from the key sheet 101 according to the twelfth embodiment in structure of a soft-feel layer 119. That is, in the soft-feel layer 119, a medium layer 120 is formed between the skin layer 104 and the first decorative layer 105. Other structural details are the same as those of the key sheet 101.

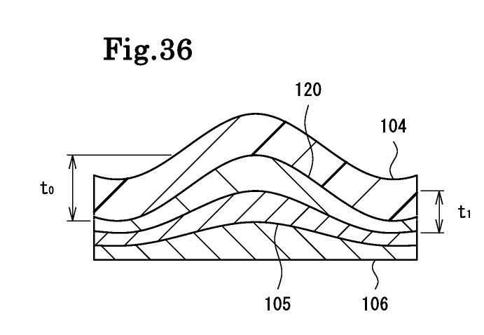

The medium layer 120 is a layer formed by printing on the back surface of the skin layer 104 so as to reduce a height difference in corrugation in the asperity shape formed on the back surface of the skin layer 104. The medium layer 120 is formed of a translucent and elastic polymer material in a non-uniform layer thickness. In other words, a film thickness of the medium layer 120 is larger near the bottoms of the recessed portions of the skin layer 104, becomes gradually smaller from the recessed portions to the protruding portions, and is smallest over the protruding portions. While a back surface of the medium layer 120 is formed in an asperity shape, owing to the layer thickness as described above, a height difference t₁ in corrugation of the medium layer 120 is smaller than a height difference t₀ in corrugation of the skin layer 104 (FIG. 36).

As a material for the medium layer 120, there may be provided an ink and a paint applicable to the skin layer 104.

The key sheet 118 is manufactured as follows. First, the asperity shape is transferred and molded onto the front and back surfaces of the skin layer 104 with use of a mold-release sheet or a die. Next, the medium layer 120, the first decorative layer 105, and the second decorative layer 106 are formed in the stated order by printing on the back surface of the skin layer 104. Lastly, the back surface of the second decorative layer 106 and the front surface of the porous layer 107, and the back surface of the porous layer 107 and the front surface of the base sheet 102 are bonded to each other with the bonding layers 110, respectively. In this manner, the key sheet 118 is obtained.

In the key sheet 118, the medium layer 120 reduces the height difference in corrugation in the asperity shape formed on the back surface of the skin layer 104. Thus, it is possible to prevent edge portions of the first decorative layer 105 from bleeding, and hence possible to accurately provide the first decorative layer 105. Further, the medium layer 120 is transparent, and hence the hue of the first decorative layer 105 does not blur. In addition, the medium layer 120 is elastic, and hence it is possible to avoid a soft touch feeling from being impaired.

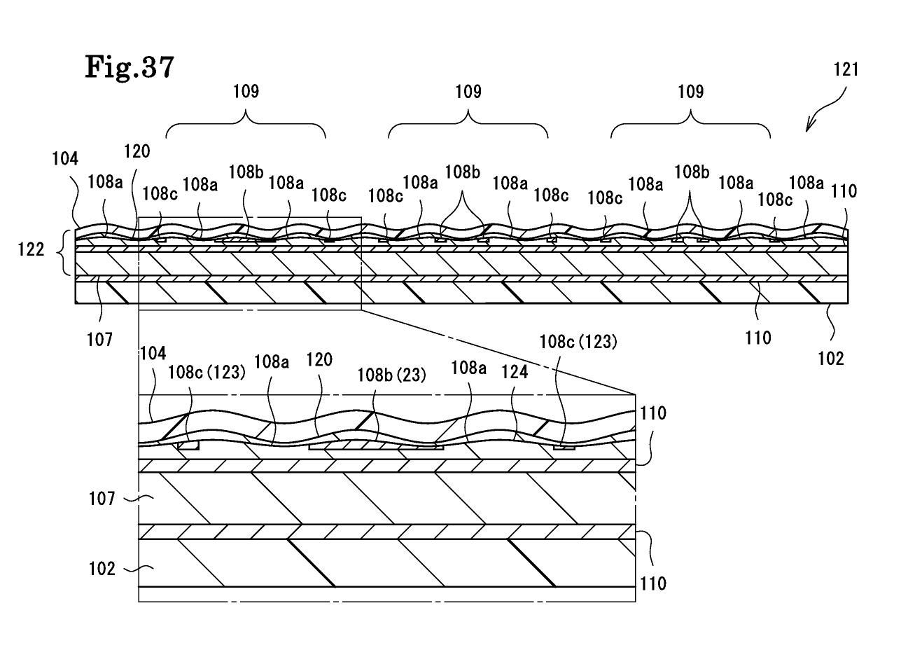

### Fourteenth Embodiment (FIG. 37)

FIG. 37 illustrates a key sheet 121 according to the fourteenth embodiment. FIG. 37 is a sectional view of the key sheet 121. The key sheet 121 according to the fourteenth embodiment is different from the key sheet 118 according to the thirteenth embodiment in structure of a first decorative layer 123 and a second decorative layer 124 in a soft-feel layer 122. Other structural details are the same as those of the key sheet 118.

The first decorative layer 123 forms the display portions 108b for displaying display elements and the partition lines 108c for surrounding the pressing-operation parts 109. In addition, the first decorative layer 123 is formed in a non-uniform layer thickness on the back surface of the medium layer 120. In other words, a film thickness of the first decorative layer 123 is larger near bottoms of the recessed portions of the medium layer 120, becomes gradually smaller from the recessed portions to protruding portions, and is smallest over the protruding portions.

The second decorative layer 124 forms the background portions 108a. In this context, the second decorative layer 124 in this embodiment is formed as a “metallic layer” formed of a paint containing metal foil.

The key sheet 121 is manufactured as follows. First, the asperity shape is transferred and molded onto the front and back surfaces of the skin layer 104 with use of a mold-release sheet or a die. Next, the medium layer 120, the first decorative layer 123, and the second decorative layer 124 are formed in the stated order by printing on the back surface of the skin layer 104. Lastly, a back surface of the second decorative layer 124 and the front surface of the porous layer 107, and the back surface of the porous layer 107 and the front surface of the base sheet 102 are bonded to each other with the bonding layers 110, respectively. In this manner, the key sheet 121 is obtained.

In the key sheet 121, the second decorative layer 124 is formed as the “metallic layer.” Thus, it is possible to realize a brand-new design which has a metallic outward appearance and by which a soft touch feeling can be obtained at the time of a pressing operation.

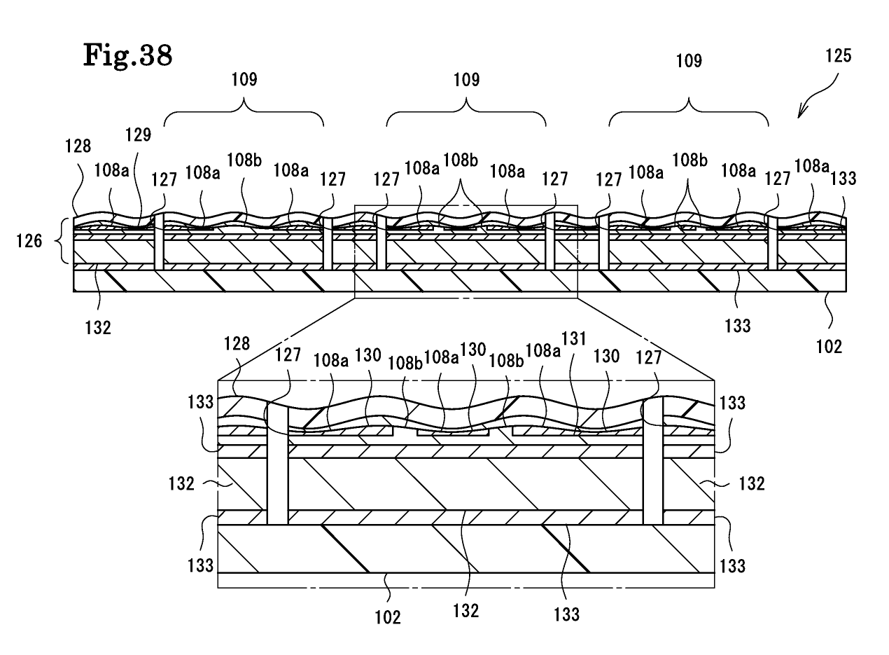

### Fifteenth Embodiment (FIG. 38)

FIG. 38 illustrates a key sheet 125 according to the fifteenth embodiment. FIG. 38 is a sectional view of the key sheet 125. The key sheet 125 according to the fifteenth embodiment is different from the key sheet 118 according to the thirteenth embodiment in structure of a soft-feel layer 126. That is, in this embodiment, instead of partition lines constituted by the first decorative layer or the second decorative layer, through-holes 127 are formed, which pass through the soft-feel layer 126 in a thickness direction thereof. The soft-feel layer 126 is constituted by a skin layer 128, a medium layer 129, a first decorative layer 130, a second decorative layer 131, and a porous layer 132 laminated in the stated order from a front surface side. Other structural details are the same as those of the key sheet 118.

Similarly to the key sheet 118 according to the thirteenth embodiment, the key sheet 125 is manufactured by forming the soft-feel layer 126 and the base sheet 102 which are not provided with the through-holes 127, and then applying a blade from above the skin layer 128 so as to form the through-holes 127 passing through the skin layer 128, the medium layer 129, the first decorative layer 130, the second decorative layer 131, the porous layer 132, and bonding layers 133. In this manner, the key sheet 125 is obtained.

In the key sheet 125, the through-holes 127 are provided as the partition lines. Thus, it is possible to partition display elements with the through-holes 127, to partition the display elements adjacent to each other, and possible to cause pressing-operation parts to be clearly visible. Further, the “partition lines” can be distinguished also with touch feelings.

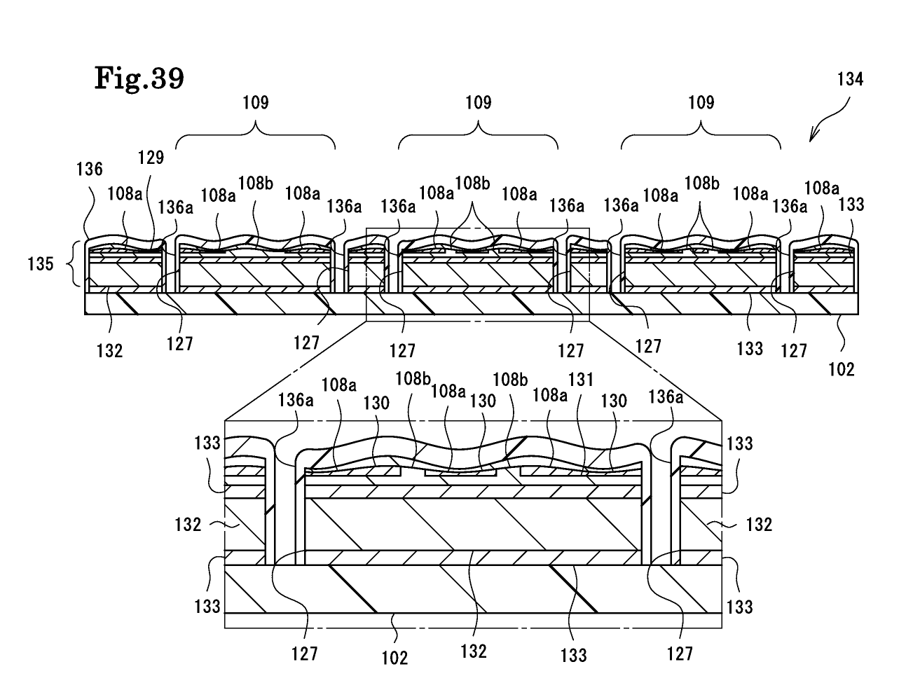

### Sixteenth Embodiment (FIG. 39)

FIG. 39 illustrates a key sheet 134 according to the sixteenth embodiment. FIG. 39 is a sectional view of the key sheet 134. The key sheet 134 according to the sixteenth embodiment is different from the key sheet 125 according to the fifteenth embodiment in structure of a soft-feel layer 135. That is, in this embodiment, edge portions of a skin layer 136 extend so as to form protective portions 136a for covering a side surface of an edge portion of each of the medium layer 129, the first decorative layer 130, the second decorative layer 131, the porous layer 132, and the bonding layers 133. Other structural details are the same as that of the key sheet 125.

Similarly to the key sheet 125 according to the fifteenth embodiment, the key sheet 134 is manufactured by forming the soft-feel layer 135 and the base sheet 102 which are not provided with the through-holes 127, and after that, by pressing the soft-feel layer 135 by thermal-compression bonding or ultrasonic welding from the skin layer 136 side. Then, along with cutting of the medium layer 129, the first decorative layer 130, the second decorative layer 131, the porous layer 132, and the bonding layers 133, the edges of those layers are covered with the protective portions 136a of the skin layer 136 so as to form the through-holes 127. In this manner, the key sheet 134 is obtained.

In the key sheet 134, the protective portions 136a are provided on the side surfaces of the edge portions of the porous layer 132 so as not to expose the porous layer 132 to the outside. Thus, it is possible to enhance durability of the porous layer 132.

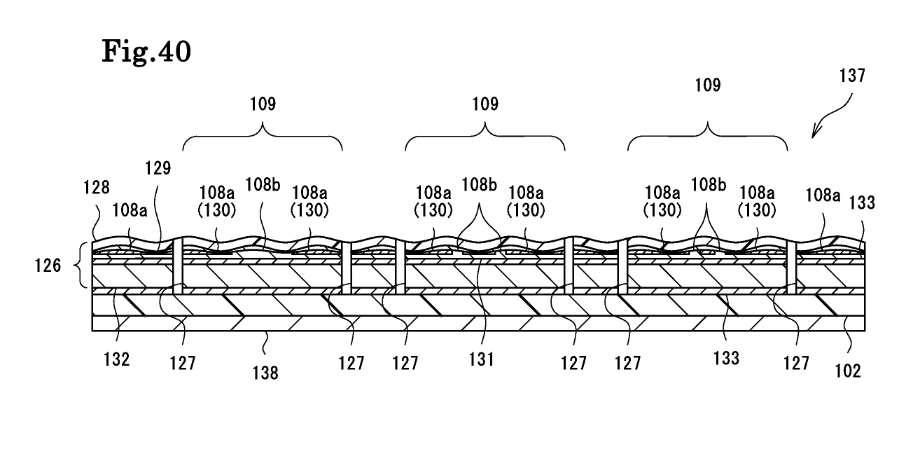

### Seventeenth Embodiment (FIG. 40)

FIG. 40 illustrates a key sheet 137 according to the seventeenth embodiment. FIG. 40 is a sectional view of the key sheet 137. The key sheet 137 according to the seventeenth embodiment is structurally different from the key sheet 125 according to the fifteenth embodiment in that an EL member 138 is provided on the back surface of the base sheet 102. In this embodiment, the base sheet 102 and the second decorative layer 131 are translucent. Other structural details are the same as those of the key sheet 125.

Similarly to the key sheet 125 according to the fifteenth embodiment, the key sheet 137 is manufactured by forming a key sheet including the base sheet 102 and the soft-feel layer 126, and after that, the EL member 138 is bonded onto the back surface of the base sheet 102 with an translucent adhesive (not shown). In this manner, the key sheet 137 is obtained. Note that, instead of bonding the EL member 138 onto the back surface of the base sheet 102 with an adhesive as in this embodiment, the EL member 138 may be directly formed by printing on the back surface of the base sheet 102.

According to the key sheet 137, at the time of backlight illumination, it is possible to differentiate brightness of light transmitting through the base sheet 102 and the through-holes 127 and brightness of light transmitting through the background portions 108a of the second decorative layer 131 from each other. As a result, it is possible to realize a design with characteristic illumination properties.

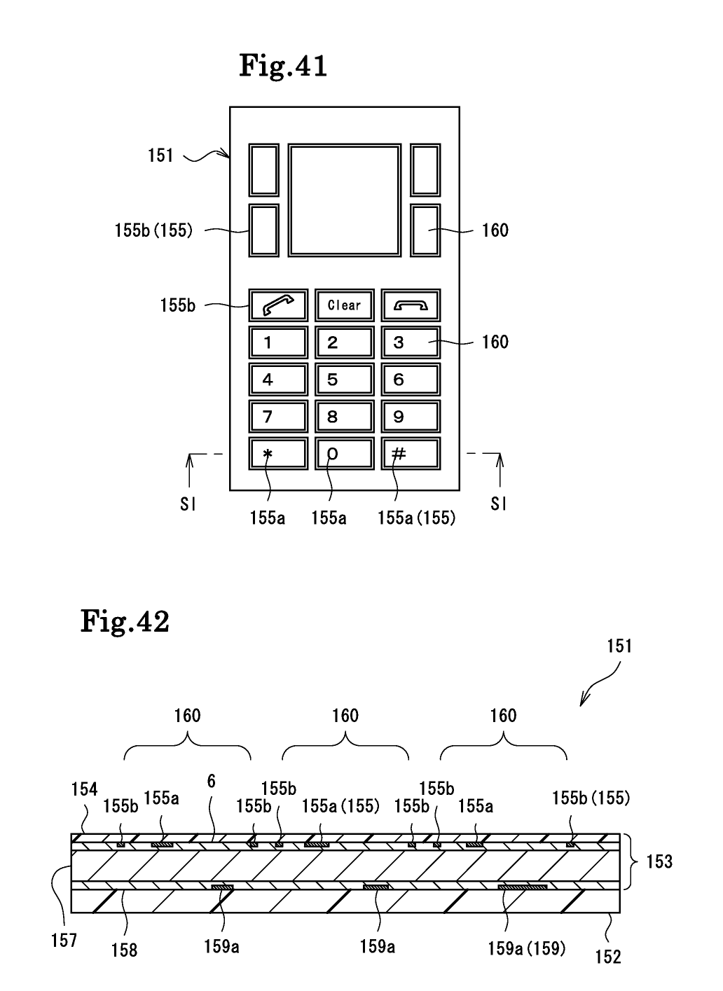

### Eighteenth Embodiment (FIGS. 41 to 43)

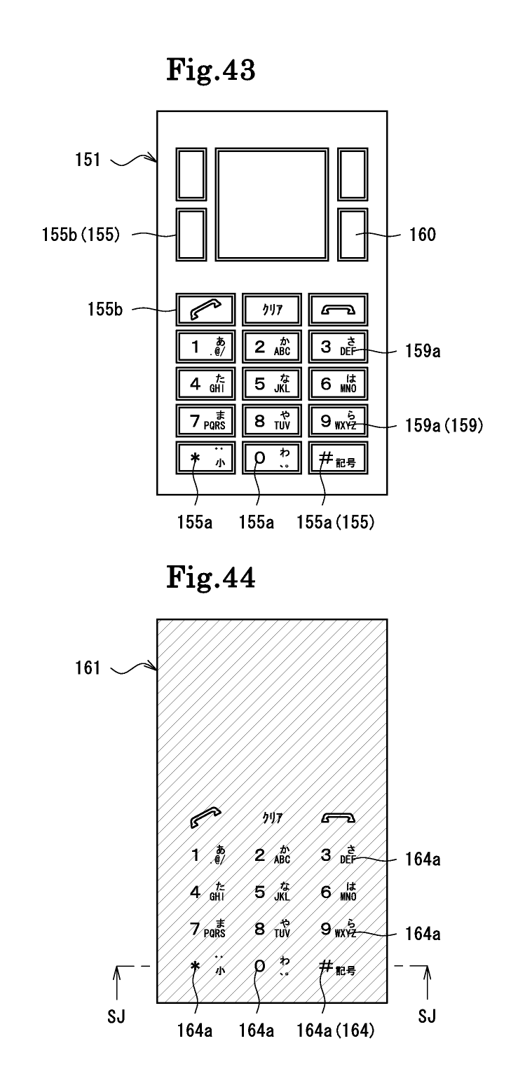

FIGS. 41 to 43 illustrate a key sheet 151 according to the eighteenth embodiment. FIG. 41 is a plan view of the key sheet 151, FIG. 42 is a sectional view of the key sheet 151, which is taken along the line SI-SI, and FIG. 43 is a plan view of the key sheet 151 in an illumination state. The key sheet 151 according to the eighteenth embodiment includes a base sheet 152 and a soft-feel layer 153, the soft-feel layer 153 being constituted by a skin layer 154, first decorative portions 155, a bonding layer 156, a porous layer 157, a bonding layer 158, and second decorative portions 159 provided in the stated order from an operating surface (front surface) side.

The skin layer 154 is an outermost layer providing a soft touch feeling, and is formed of a translucent polymer material to be formed into a sheet-like shape. As a material for the skin layer 154, similarly to that of the skin layer 2, there may be used a resin or elastomer excellent in abrasion resistance, waterproofness, and chemical resistance. Examples thereof include polyolefin-based resins such as polyethylene and polypropylene, polystyrene-based resins such as polystyrene and a styrene-maleic anhydride copolymer, polyurethane-based resins, polyvinyl chloride-based resins, and thermoplastic elastomers. Of those, excellent soft touch feeling can be obtained when using polyurethane-based resins.

In addition, it is possible to use resin components obtained by mixing expandable beads, hollow beads, elastic beads, inorganic materials, or the like with the resins or the elastomer forming the skin layer 154. With addition of the beads and the inorganic materials, it is possible to form small asperities on the skin layer 154 so as to provide various touch feelings. The expandable beads are beads that become hollow when heated, and as a material for the expandable beads, there are exemplified polyurethane, an acrylic-urethane copolymer, polystyrene, and a styrene-isoprene copolymer. The hollow beads are a hollow spherical object, and as a material for the hollow beads, there are exemplified copolymers of vinylidene chloride and acrylonitrile and a across-linked acrylic polymer. The elastic beads are resin particles which have an elastic recovery property, when pressure is applied until a shape of the beads changes and then released. Examples thereof include polyurethane resins, acrylic-urethane resins, polystyrene resins, and a styrene-isoprene copolymer. Examples of the inorganic materials include silicon dioxide (SiO₂; also referred to as silica and silicic anhydride), hydrous silicate (SiO₂·xH₂O), and hydrous aluminum silicate (Al₂O₃9SiO₂·xH₂O).

Similarly, the above-mentioned resins or elastomer may be mixed with various additives including a colorant such as a pigment or a dye, an antioxidant, and an ultraviolet absorber.

It is preferred that a thickness of the skin layer 154 as described above range from 5 μm to 200 μm. This is because the skin layer 154 having a thickness of less than 5 μm is liable to suffer breakage owing to its poor durability and the skin layer 154 having a thickness of more than 200 μm impairs a touch feeling with respect to the operator owing to its high rigidity, which leads to difficulty in achieving the soft touch feeling.

The first decorative portions 155 are formed in an application layer formed by printing on a back surface of the skin layer 154, and are constituted by display portions 155a displaying display elements such as letters, numerals, and symbols, and rectangular partition lines 155b for partitioning the display portions 155a and surrounding pressing-operation parts 160. The display portions 155a indicate display elements mainly used in making telephone calls. As a material for the first decorative portions 155, there may be provided an ink and a paint applicable to the skin layer 154.

The bonding layer 156 is a layer for bonding the skin layer 154 and the porous layer 157 to each other, and is formed of a translucent adhesive or a translucent pressure-sensitive adhesive. Examples of the usable translucent adhesives for the bonding layer 156 include an adhesive film, a pressure-sensitive adhesive film, and a hot-melt adhesive.

The porous layer 157 is an easily-depressed layer laminated on the back surface side of the skin layer 154, and is formed of a foamed body with low compression elasticity. In addition, the porous layer 157 is translucent, and the second decorative portions 159 constitute display portions 159a displaying small display elements. Thus, the porous layer 157 is structured as an open-cell foam layer in which foams are continuous with each other in a thickness direction, and has a thickness ranging from 250 μm to 450 μm. The second decorative portions 159 are visible even in a non-illumination state when the thickness is less than 250 μm, and the second decorative portions 159 are less visible even in an illumination state when the thickness is more than 450 μm. A material for the porous layer 157 is a resin or an elastomer which may be formed into a foam, and similarly to the material for the surface layer 154, there are exemplified polyolefin-based resins such as polyethylene and polypropylene, polystyrene-based resins such as a polystyrene and styrene-maleic anhydride copolymer, polyurethane-based resins, polyvinyl chloride-based resins, and thermoplastic elastomers.

Note that, when the second decorative portions 159 indicate pattern and characters unlike in this embodiment, it is possible to obtain design effects even when the second decorative portions 159 lit up in an illumination state are unclear to some extent. Thus, it is possible to structure the porous layer as a closed-cell foam layer, and possible to set the thickness of the porous layer to range from 250 μm to 700 μm.

The bonding layer 158 is a layer for bonding the base sheet 152 and the porous layer 157 to each other, and is formed of a translucent adhesive or a translucent pressure-sensitive adhesive. Examples of the translucent adhesives which can be used for the bonding layer 158 include, similarly to the bonding layer 156, an adhesive film, a pressure-sensitive adhesive film, and a hot-melt adhesive.

The second decorative portions 159 are formed in an application layer formed by printing on a front surface of the base sheet 152, and are constituted by display portions 159a displaying display elements such as letters, numerals, and symbols. The display portions 159a indicate display elements mainly used in writing e-mails. As a material for the second decorative portions 159, there may be provided an ink and a paint applicable to the base sheet 152.

The base sheet 152 has a function of providing formability of the key sheet 151, and is formed of a translucent resin. With provision of pressers on a back surface of the base sheet 152, it is possible to enhance pressing operability. The base sheet 152 may be formed of a translucent thermoplastic resin and a thermosetting resin. As a material for the base sheet 152, similarly to that of the base sheet 5, there are exemplified an acrylic resin, a styrene resin, a polyester resin, a polyolefin resin, a silicone resin, an epoxy resin, and a urethane-based resin. It is preferred that a thickness of the base sheet 152 range from 100 μm to 500 μm. This is because the base sheet 152 having a thickness of less than 100 μm may suffer breakage in post-processing owing to its poor strength, and has difficulty in maintaining a shape of the key sheet 151 owing to its poor rigidity. The base sheet 152 having a thickness of more than 500 μm is difficult to deflect owing to its high rigidity, which leads to an increase in pressing load so as to deteriorate operability in a case of a key sheet for an operation by pressing input.

Description is made of an example of a manufacturing method for the key sheet 151. First, after forming the first decorative portions 155 by printing on the back surface of the skin layer 154, the bonding layer 156 is formed by printing on the entire back surface of the skin layer 154. Then, the bonding layer 156 is laminated on a front surface of the porous layer 157, and is heated and pressed from the skin layer 154 side with use of a thermal compressor or the like so as to bond the skin layer 154 and the porous layer 157 to each other with the bonding layer 156 as a hot-melt adhesive layer. Meanwhile, after forming the second decorative portions 159 by printing on a front surface of the base sheet 152, the bonding layer 158 is formed by printing on the entire front surface of the base sheet 152. Lastly, the bonding layer 158 is laminated on a back surface of the porous layer 157, and is heated and pressed from the base sheet 152 side with use of a thermal compressor or the like so as to bond the base sheet 152 and the porous layer 157 to each other with the bonding layer 158 as a hot-melt adhesive layer. In this manner, the key sheet 151 is manufactured.

According to the key sheet 151, an operating surface is constituted by the skin layer 154 of the soft-feel layer 153, and hence it is possible to provide a soft touch feeling at the time of a pressing operation. In addition, the porous layer 157 is formed of a foamed body with low compression elasticity, and hence it is possible to facilitate depression of the operating surface of the soft-feel layer 153 owing to elasticity of the porous layer 157. In this manner, it is possible to realize a key sheet 151 with a soft touch feeling.

Further, the display portions 155a and the partition lines 155b of the first decorative portions 155 are provided on the back surface side of the skin layer 154. Thus, it is possible to prevent abrasion of the first decorative portions 155 at the time of a pressing operation. In addition, the first decorative portions 155 are visible through the translucent skin layer 154, and hence it is possible to provide high visibility to the display portions 155a and the partition lines 155b. As a result, it is possible to cause the display elements and the pressing-operation parts 160 to be clearly visible.

The porous layer 157 is formed of an open-cell foam layer in which foams are continuous with each other in a thickness direction, and has a thickness ranging from 250 μm to 450 μm. Thus, in a non-illumination state, it is possible to cause the followings to be visible: the display portions 155a and the partition lines 155b of the first decorative portions 155 provided on the front surface side of the porous layer 157, and possible to indicate display elements mainly used in making telephone calls in the pressing-operation parts 160 (FIG. 41). In an illumination state, it is possible to cause the second decorative portions 159 lit up together with the first decorative portions 155, and possible to clearly indicate small display elements mainly used in writing e-mails in the pressing-operation parts 160 (FIG. 43). That is, decorative designs can be switched between the non-illumination state and the illumination state, and hence it is possible to realize a key sheet 151 with a brand-new design.

### Modification of Eighteenth Embodiment

In the key sheet 151 according to the eighteenth embodiment, the display elements mainly used in making telephone calls are indicated by the display portions 155a and the partition lines 155b of the first decorative portions 155, and the display elements mainly used in writing e-mails are indicated by the second decorative portions 159. Meanwhile, in a modification, it is possible to indicate all the display elements with the first decorative portions and possible to form the partition lines with the second decorative portions. In this modification, all the display elements are provided on the back surface of the skin layer 154. Thus, even fine display elements are clearly visible, and the partition lines can be lit up only in the illumination state. Further, in another modification, it is possible to indicate all the display elements and the partition lines with the first decorative portions, and possible to indicate designs such as patterns, characters, and logos. Further, in this modification, the porous layer may be structured as a closed-cell foam layer, and a thickness of the porous layer may set to range from 250 μm to 700 μm.

### Nineteenth Embodiment (FIGS. 44 to 46)

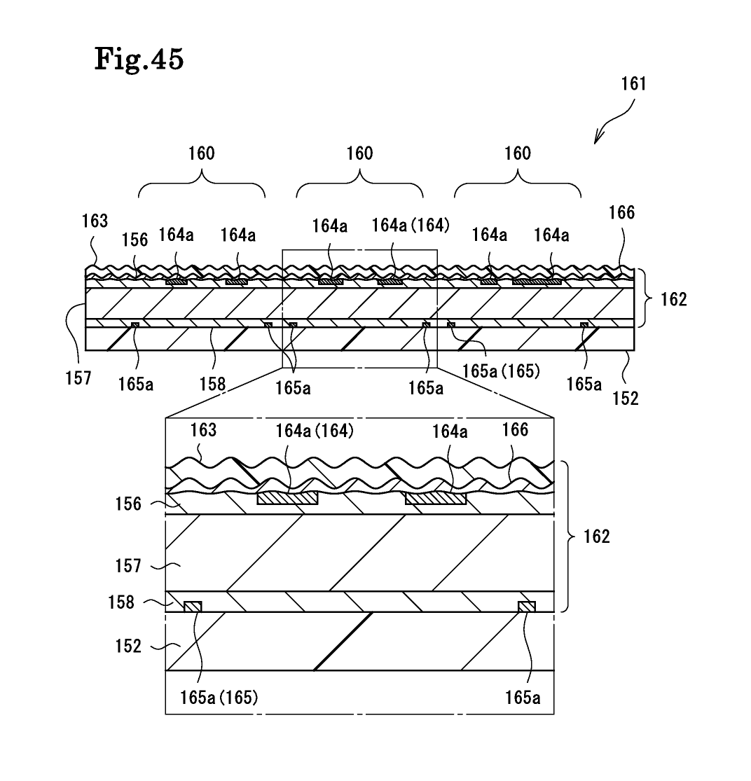

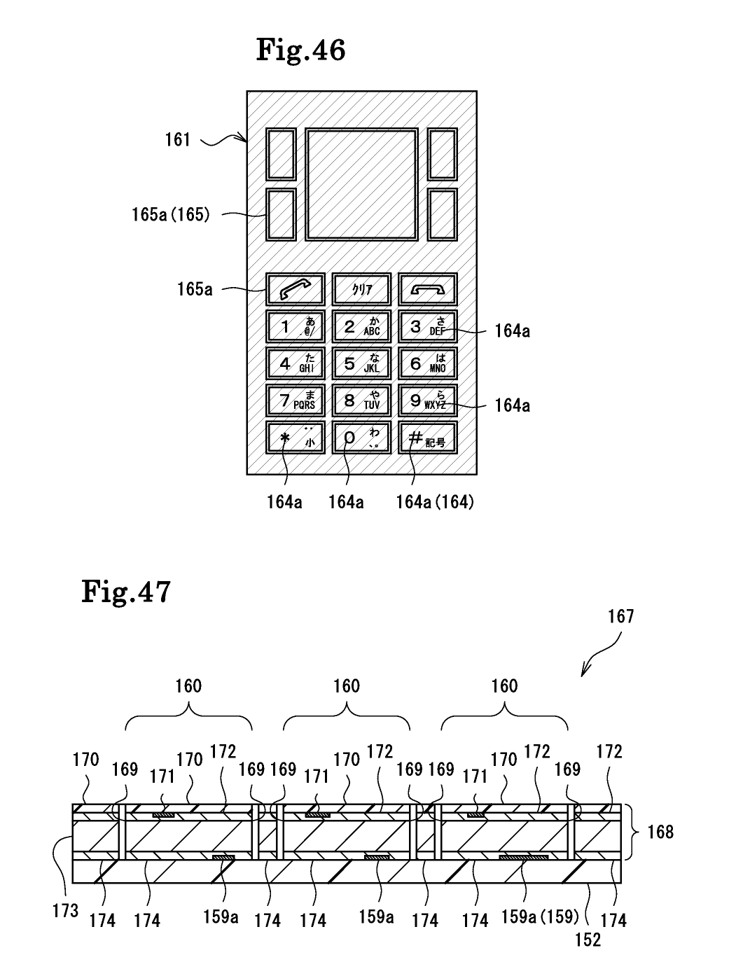

FIGS. 44 to 46 illustrate a key sheet 161 according to the nineteenth embodiment. FIG. 44 is a plan view of the key sheet 161, FIG. 45 is a sectional view of the key sheet 161, which is taken along the line SJ-SJ, and FIG. 46 is a plan view of the key sheet 161 in an illumination state. The key sheet 161 according to the nineteenth embodiment is different from the key sheet 151 according to the eighteenth embodiment in structure of a soft-feel layer 162. That is, the soft-feel layer 162 is constituted by a skin layer 163, first decorative portions 164, the bonding layer 156, the porous layer 157, the bonding layer 158, second decorative portions 165, and in addition, a medium layer 166 formed on a back surface of the skin layer 163. Other structural details are the same as those of the key sheet 151.

A front surface and a back surface of the skin layer 163 are formed in an asperity shape of inclined surfaces, the asperity shape being formed in a stripe pattern in plan view. In this context, a depth of recessed portions in the asperity shape ranges from 5 μm to 500 μm. The pattern of the asperity shape is less visible when the recessed portions have a depth of less than 5 μm. In addition, the first decorative layer is formed as a substantially flat layer, and hence it is difficult to visualize change in hue of the first decorative layer. Further, it is difficult to form the first decorative layer with respect to the recessed portion in the asperity shape when the recessed portions have a depth of more than 500 μm.

The first decorative portions 164 form display portions 164a displaying display elements, and the second decorative portions 165 form rectangular partition lines 165a.

The medium layer 166 is a layer formed by printing on the back surface of the skin layer 163 so as to reduce a height difference in corrugation in the asperity shape formed on the back surface of the skin layer 163. The medium layer 166 is formed of a translucent and elastic polymer material in a non-uniform layer thickness. In other words, a film thickness of the medium layer 166 is larger near the bottoms of the recessed portions of the skin layer 163, becomes gradually smaller from the recessed portions to the protruding portions, and is smallest over the protruding portions. While a back surface of the medium layer 166 is formed in an asperity shape, owing to the layer thickness as described above, a height difference in corrugation of the medium layer 166 is smaller than a height difference in corrugation on the back surface of the skin layer 163. As a material for the medium layer 166, there may be used an ink and a paint applicable to the skin layer 163.

The key sheet 161 is manufactured as follows. First, the asperity shape is transferred and molded onto the front and back surfaces of the skin layer 163 with use of a mold-release sheet or a die. Next, the medium layer 166 is formed by printing on the back surface of the skin layer 163, and then the first decorative portions 164 and the bonding layer 156 are formed by printing. Then, the skin layer 163 and the porous layer 157 are bonded to each other with the bonding layer 156 as a hot-melt adhesive layer. Meanwhile, the second decorative portions 165 and the bonding layer 158 are formed by printing on the front surface of the base sheet 152. Lastly, the base sheet 152 and the porous layer 157 are bonded to each other with the bonding layer 158 as a hot-melt adhesive layer. In this manner, the key sheet 161 is obtained.

In the key sheet 161, even when the back surface of the skin layer 163 is an asperity surface, the medium layer 166 reduces a height difference in corrugation in the asperities. Thus, it is possible to accurately provide the first decorative portions 164, and hence possible to realize clear display portions 164a in the first decorative portions 164. In this context, even when the medium layer 166 is provided, the medium layer 166 is transparent, and hence the first decorative portions 164 are prevented from being less visible. In addition, the medium layer 166 is elastic, and hence a soft touch feeling is not impaired.

The first decorative portions 164 form the display portions 164a displaying display elements, and the second decorative portions 165 form the partition lines 165a. Thus, even the fine display portions 164a are clearly visible in a non-illumination state (FIG. 44), and the partition lines 165a surrounding the display portions 164a can be lit up in an illumination state (FIG. 46). Thus, in the illumination state, it is possible to cause the pressing-operation parts 160 to be more visible and possible to prevent misinputs.

The front surface of the skin layer 163 is an asperity surface, and hence it is possible to reduce a frictional coefficient on the front surface of the skin layer 163, and possible to provide a smooth front surface. As a result, it is possible to increase a soft touch feeling.

### Twentieth Embodiment (FIG. 47)

FIG. 47 illustrates a key sheet 167 according to the twentieth embodiment. FIG. 47 is a sectional view of the key sheet 167. The key sheet 167 according to the twentieth embodiment is different from the key sheet 151 according to the eighteenth embodiment in structure of a soft-feel layer 168. That is, in this embodiment, instead of partition lines constituted by the first decorative portions, through-holes 169 are formed, which pass through the soft-feel layer 168 in a thickness direction thereof. The soft-feel layer 168 is constituted by a skin layer 170, first decorative portions 171, a bonding layer 172, a porous layer 173, a bonding layer 174, and the second decorative portions 159 laminated in the stated order from a front surface side. Other structural details are the same as those of the key sheet 151.

Similarly to the key sheet 151 according to the eighteenth embodiment, the key sheet 167 is manufactured by laminating, on the base sheet 152, the soft-feel layer 168 which is not provided with the through-holes 169, and then applying a blade from above the skin layer 170 so as to form the through-holes 169 passing through the skin layer 170, the bonding layer 172, the porous layer 173, and the bonding layer 174. In this manner, the key sheet 167 is obtained.

According to the key sheet 167, the through-holes 169 are provided as partition lines, and hence the pressing-operation parts 160 can be confirmed also with touch feelings owing to the through-holes 169. Further, at the time of performing a pressing operation, the key sheet 167 is easily deflected, and hence pressing load can be suppressed. As a result, it is possible to enhance pressing operability.

In an illumination state, backlight transmits through the translucent base sheet 152 so as to be emitted through the through-holes 169 to the outside. Thus, it is possible to differentiate brilliance of light transmitting through the pressing-operation parts 160 and brilliance of light transmitting through the through-holes 169 from each other. As a result, it is possible to realize a key sheet 167 with characteristic illumination properties.

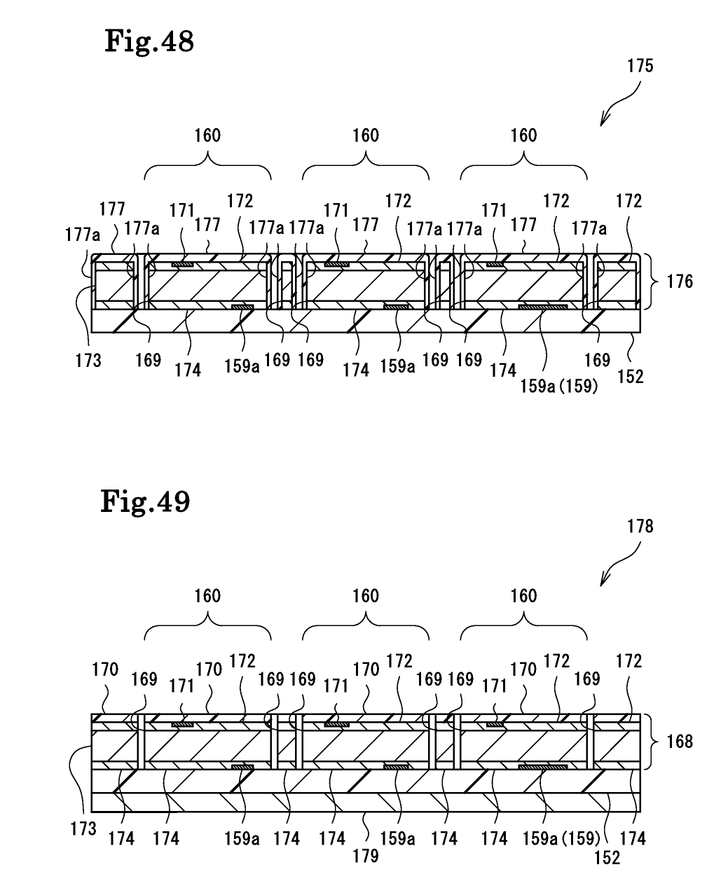

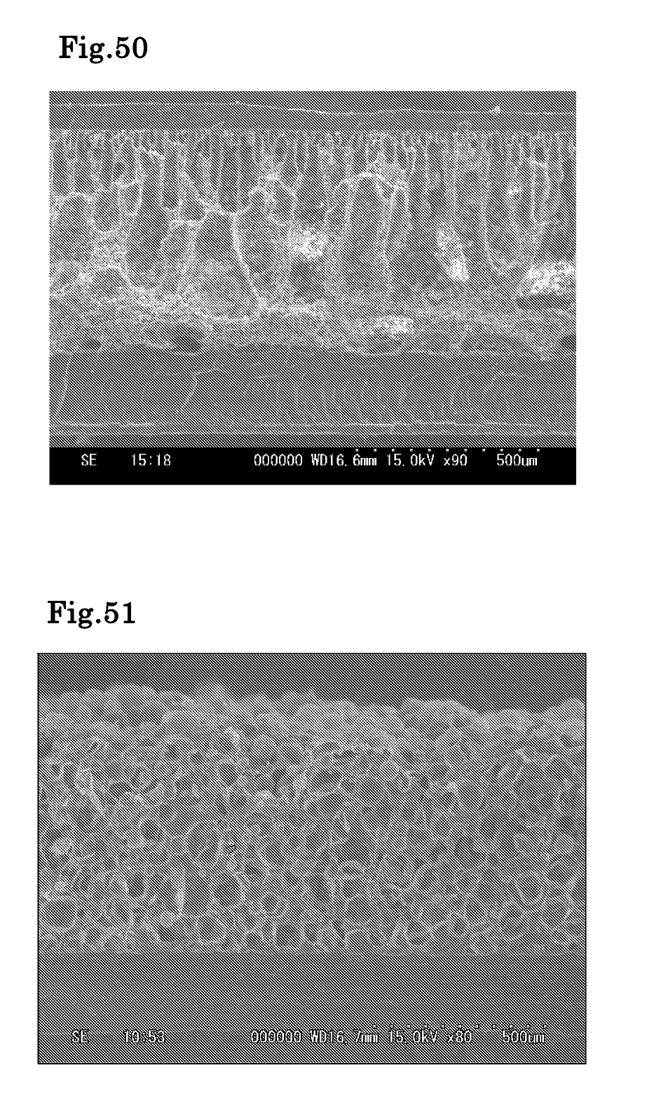

### Twenty-First Embodiment (FIG. 48)

FIG. 48 illustrates a key sheet 175 according to the twenty-first embodiment. FIG. 48 is a sectional view of the key sheet 175. The key sheet 175 according to the twenty-first embodiment is different from the key sheet 167 according to the twentieth embodiment in structure of a soft-feel layer 176. That is, in this embodiment, edge portions of a skin layer 177 are extended so as to form protective portions 176a for covering a side surface of an edge portion of each of the bonding layer 172, the porous layer 173, and the bonding layer 174. Other structural details are the same as that of the key sheet 167.

Similarly to the key sheet 167 according to the twentieth embodiment, the key sheet 175 is manufactured by laminating, on the base sheet 152, the soft-feel layer 176 which is not provided with the through-holes 169, and after that, by pressing the soft-feel layer 176 by thermal-compression bonding or ultrasonic welding from the skin layer 177 side. Then, along with forming of the through-holes 169 through the bonding layer 172, the porous layer 173, and the bonding layer 174, the edge portions of those layers are covered with the protective portions 177a of the skin layer 177. In this manner, the key sheet 175 is obtained.

In the key sheet 175, the protective portions 177a for covering the side surfaces of the edge portions of the porous layer 173 are provided, and hence the porous layer 173 is not exposed to the outside. Thus, it is possible to enhance durability of the porous layer 173.

### Twenty-Second Embodiment (FIG. 49)

FIG. 49 illustrates a key sheet 178 according to the twenty-second embodiment. FIG. 49 is a sectional view of the key sheet 178. The key sheet 178 according to the twenty-second embodiment is structurally different from the key sheet 167 according to the twentieth embodiment in that an EL member 179 is provided on the back surface of the base sheet 152. Other structural details are the same as those of the key sheet 167.

Similarly to the key sheet 167 according to the twentieth embodiment, the key sheet 178 is manufactured by forming a key sheet including the base sheet 152 and the soft-feel layer 168, and after that, by bonding the EL member 179 onto the back surface of the base sheet 152 with a translucent adhesive (not shown). In this manner, the key sheet 178 is obtained. Note that, instead of bonding the EL member 179 onto the back surface of the base sheet 152 with an adhesive as in this embodiment, the EL member 179 may be directly formed by printing on the back surface of the base sheet 152.

According to the key sheet 178, the EL member 179 is provided on the back surface of the base sheet 152, and hence the second decorative portions 159 can be illuminated by plane light-emission. As a result, it is possible to enhance visibility of edges of the second decorative portions 159.

### Modification of Twenty-Second Embodiment

The case is exemplified where the key sheet 178 according to the twenty-second embodiment is obtained by providing the EL member 179 on the back surface of the base sheet 152 in the key sheet 167 according to the twentieth embodiment. Meanwhile, in a modification, it is possible to provide the EL member 179 on the back surface of each of the key sheet 151, 161, and 175 according to the above-mentioned other embodiments.

Other modifications: While specific description has been made of the various embodiments, the present invention is not limited to those embodiments. In order to meet various demands, it is possible to provide a key sheet having another structure obtained by appropriately combining the various components illustrated in the embodiments of the various types.

In this context, the following examples are provided: the porous layer constituted by the hair-implanted layer illustrated in the key sheets of the second type may be interchangeable with the porous layers illustrated in the embodiments of the other types, and the decorative portion illustrated in the key sheets of the fourth type may be interchangeable with the decorative portions illustrated in the embodiments of the other types.

### Examples

Next, while more detailed description is made of the key sheets of the second type of the present invention by way of examples, the key sheets of the second type of the present invention are not limited to the following examples.

1. Manufacture of Key Sheet:

### Example 21

With use of the skin layer (54) made of a translucent urethane-based resin and having a thickness of 50 μm, the character layer (55) was provided by printing a translucent vinyl-acetate-based ink on the back surface (54b) of the skin layer (54). Meanwhile, the hair-implanted layer (57) having an average thickness of 370 μm was formed on the front surface (53a) of the base sheet (53) formed of a translucent polyethylene terephthalate (PET) film having a thickness of 188 μm. The hair-implanted layer (57) was molded by the following: applying the support layer (57a) formed of a thermosetting adhesive of a urethane-based resin and having a thickness of 50 μm on the front surface (53a) of the base sheet (53); implanting the piles (57b) made of nylon and having a fiber length of 0.4 mm and a linear density of 0.5 D in the support layer (57a) with static electricity; and curing the support layer (57a) through thermal drying. Then, laminating was performed on the character layer (55) and the hair-implanted layer (57) which sandwiched the bonding layer (56) formed of a vinyl-acetate-based adhesive therebetween so as to complete the key sheet (51) constituted by the soft-feel layer (52) and the base sheet (53), the soft-feel layer (52) being constituted by the skin layer (54), the character layer (55), the bonding layer (56), and the hair-implanted layer (57). This was used as a sample 1.

### Example 22

On a back surface of a skin layer made of a translucent urethane-based resin and having a thickness of 50 μm, a character layer was provided by printing a translucent vinyl-acetate-based ink. On a back surface of the character layer, a foam layer made of a urethane-based resin and having a thickness of 300 μm and a base sheet formed of a translucent polyethylene terephthalate (PET) film and having a thickness of 188 μm were laminated through an intermediation of a bonding layer in the stated order. In this manner, a key sheet was manufactured. This was used as a sample 2.

2. Evaluation of Key Sheet:

As illustrated in FIG. 29, evaluation of brightness in an illumination state was performed on the samples 1 and 2 manufactured in the above-mentioned examples.

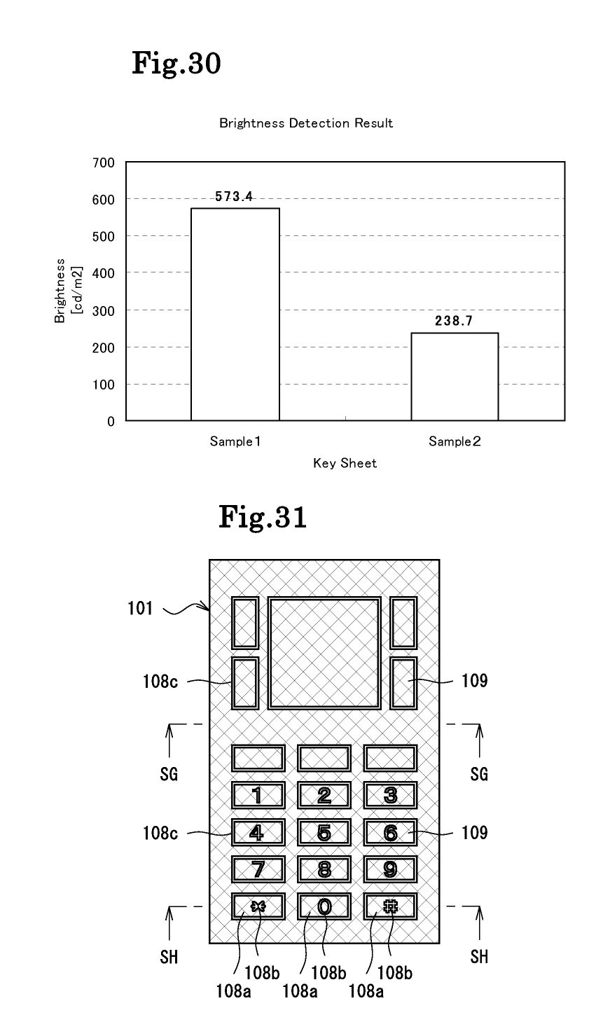

“Detection of brightness”: Each of the samples was placed on a center of an upper surface of a light table (90) with a light source having brightness of 854.1 cd/m², and the upper surface except an area corresponding to the samples was covered with a lightproof masking sheet (91). Brightness on an operating surface side of the samples was detected with a brightness detector (92) (PR-902 manufactured by Photo Research, Inc.). FIG. 30 shows the results.

As shown in FIG. 30, the brightness of the sample 1 was 573.4 cd/m², and the brightness of the sample 2 was 238.7 cd/m². This is probably because light transmitting through the sample 1 was less liable to be scattered through between the piles (57b) implanted in a direction crossing a plane direction of the base sheet (53), and light transmitting through the sample 2 was scattered through foams in the foam layer, with the result that the brightness on the operating surface side of the sample 1 was higher than that of the sample 2.

Next, while more detailed description is made of the key sheets of the fourth type of the present invention by way of more specific manufacturing examples of the key sheet, the key sheets of the fourth type of the present invention are not limited to the following examples.

3. Manufacture of Key Sheet:

### Example 41

On the back surface of the skin layer (154) made of a translucent urethane-based resin and having a thickness of 50 μm, the first decorative portions (155) forming the display portions (155a) and the partition lines (155b) were formed by printing a vinyl-acetate-based ink. After that, the bonding layer (156) formed of a hot-melt adhesive was formed by printing on the entire back surface of the skin layer (154). Then, the bonding layer (156) was laminated on the front surface of the porous layer (157) which had a thickness of 250 μm and in which open-cell foams were continuous with each other in a thickness direction, and was heated and pressed from the skin layer (154) side with use of a thermal compressor or the like so as to bond the skin layer (154) and the porous layer (157) to each other. Meanwhile, on the front surface of the base sheet (152) formed of a translucent polyethylene terephthalate (PET) film and having a thickness of 188 μm, the second decorative portions (159) forming the display portions (159a) were formed by printing a vinyl-acetate-based ink. After that, the bonding layer (158) formed of a hot-melt adhesive was formed by printing on the entire front surface of the base sheet (152). Then, the bonding layer (158) was laminated on the back surface of the porous layer (157), and was heated and pressed from the base sheet (152) side with use of a thermal compressor or the like so as to bond the base sheet (152) and the porous layer (157) to each other. In this manner, the key sheet (151) was manufactured. This was used as a sample 41.

### Example 42

With use of a porous layer (157) which had a thickness of 450 μm and in which open-cell foams were continuous with each other in a thickness direction, a key sheet (151) was manufactured in the same manner as that for the sample 41. This was used as a sample 42.

### Example 43

On the back surface of the skin layer (154) similar to that in the case of the sample 41, the first decorative portions (155) forming the display portions (155a) and the partition lines (155b) were formed by printing. Then, with the bonding layer (156) formed by printing on the entire back surface of the skin layer (154), the back surface of the skin layer (154) was bonded to a front surface of a porous layer (157) which had a thickness of 500 μm and in which open-cell foams were continuous with each other in a thickness direction. Further, on the front surface of the base sheet (152) similar to that in the case of the sample 41, the second decorative portions (159) formed in a grid pattern were formed by printing. After that, with the bonding layer (158) formed by printing on the entire front surface of the base sheet (152), the front surface of the base sheet (152) was bonded to the back surface of the porous layer (157). In this manner, the key sheet (151) was manufactured. This was used as a sample 43.

### Example 44

With use of a porous layer (157) which had a thickness of 700 μm and in which open-cell foams were continuous with each other in a thickness direction, a key sheet (151) was manufactured in the same manner as that for the sample 43. This was used as a sample 44.

### Example 45

With use of a porous layer which had a thickness of 900 μm and in which open-cell foams were continuous with each other in a thickness direction, a key sheet was manufactured in the same manner as that for the sample 43. This was used as a sample 45.

### Example 46

With use of a porous layer (157) which had a thickness of 285 μm and contained closed-cell foams, a key sheet (151) was manufactured in the same manner as that for the sample 43. This was used as a sample 46.

### Example 47

With use of a porous layer (157) which had a thickness of 390 μm and contained closed-cell foams, a key sheet (151) was manufactured in the same manner as that for the sample 43. This was used as a sample 47.

### Example 48

With use of a porous layer (157) which had a thickness of 550 μm and contained closed-cell foams, a key sheet (151) was manufactured in the same manner as that for the sample 43. This was used as a sample 48.

### Example 49

With use of a porous layer which had a thickness of 190 μm and contained closed-cell foams, a key sheet was manufactured in the same manner as that for the sample 43. This was used as a sample 49.

4. Manufacture of Key Sheet:

Evaluation of visibilities in an illumination state and a non-illumination state was performed on the first decorative portions (155) and the second decorative portions (159) of the samples 41 to 49.

“Evaluation of visibility”: Each of the samples was placed on a center of an upper surface of a light table having a built-in normal light source D65 (JIS Z 8720), and the upper surface except an area corresponding to the samples was covered with a lightproof masking sheet. Then, confirmation of visibilities in a non-light-emission state (non-illumination state) and a light-emission state (illumination state) of the light source was performed on the second decorative portions (159). Tables 1 and 2 show the results. In the tables, the phrase “confirmation failed” represents a result that more than eight out of ten evaluators were not able to confirm the second decorative portions (159), and the phrase “confirmation succeeded” represents a result that more than eight out of ten evaluators were able to confirm the second decorative portions (159). The mark “x” represents a result that effects of the present invention were not obtained, and a result that the second decorative portions (159) were confirmed in the non-illumination state and the second decorative portions (159) were not confirmed in the illumination state. The marks “∘” and “⊚” represent results that the effects of the present invention were obtained. In particular, the mark “⊚” represents a result that the second decorative portions (159) were clearly confirmed in the illumination state.

As shown in the table 1, regarding the samples 41 and 42, only the first decorative portions (155) including the display portions (155a) and the partition lines (155b) were confirmed in the non-illumination state, and the display portions (159a) were lit up with backlight in the illumination state so that both the first decorative portions (155) and the second decorative portions (159) were clearly confirmed. Further, regarding the samples 43 and 44, only the first decorative portions (155) including the display portions (155a) and the partition lines (155b) were confirmed in the non-illumination state, and the second decorative portions (159) formed in a grid pattern were lit up with the backlight in the illumination state so that the grid pattern was confirmed behind the display portions (155a) and the partition lines (155b).

Regarding the sample 45, even though the porous layer was constituted by an open-cell foam layer which is suitable to illumination and in which foams are continuous with each other in a thickness direction, the second decorative portions (159) as the display portions (159a) were not confirmed in the illumination state.

As shown in the table 2, regarding the samples 46 to 48, only the first decorative portions (155) including the display portions (155a) and the partition lines (155b) were confirmed in the non-illumination state, and the second decorative portions (159) formed in a grid pattern were lit up with the backlight in the illumination state so that the grid pattern was confirmed behind the display portions (155a) and the partition lines (155b). The grid pattern lit up with the backlight was slightly unclear.

Regarding the sample 49, even though the porous layer was constituted by a closed-cell foam layer in which light is easily scattered, the grid pattern was confirmed even in the non-illumination state.

TABLE 1

| | Sample 41 | Sample 42 | Sample 43 | Sample 44 | Sample 45 |
|---|---|---|---|---|---|
| Layer thickness of porous layer (μm) | 250 | 450 | 500 | 700 | 900 |
| Open-cell foams continuous with | | | | | |
| each other in thickness direction | | | | | |
| Evaluation of visibility of | ⊚ | ⊚ | ◯ | ◯ | X |
| second decorative layer | | | | | |
| In non-illumination state | Confirmation | Confirmation | Confirmation | Confirmation | Confirmation |
| | failed | failed | failed | failed | failed |
| In illumination state | Confirmation | Confirmation | Confirmation | Confirmation | Confirmation |
| | succeeded | succeeded | succeeded | succeeded | failed |

TABLE 2

| | Sample 46 | Sample 47 | Sample 48 | Sample 49 |
|---|---|---|---|---|
| Layer thickness of porous layer (μm) | 285 | 390 | 550 | 190 |
| Closed-cell foams | | | | |
| Evaluation of visibility of | ◯ | ◯ | ◯ | X |
| second decorative layer | | | | |
| In non-illumination state | Confirmation | Confirmation | Confirmation | Confirmation |
| | failed | failed | failed | succeeded |
| In illumination state | Confirmation | Confirmation | Confirmation | Confirmation |
| | succeeded | succeeded | succeeded | succeeded |

### INDUSTRIAL APPLICABILITY

The present invention relates to a key sheet used for operating parts of various electronic devices such as personal digital assistants, AV devices, and various keyboards. Thus, the present invention is applicable to a telecommunication device industry, an electrical appliance industry, and industries related thereto.

1. A key sheet, comprising:
a base sheet; and
a soft-feel layer laminated on a front surface side of the base sheet and having a soft touch feeling,
wherein the soft-feel layer comprises:
a translucent skin layer having the soft touch feeling; and
decorative portions visible through the skin layer.

2. A key sheet according to claim 1, wherein:
the base sheet is translucent; and
the decorative portions of the soft-feel layer comprise a character layer provided on a back surface of the skin layer and having a printed layer in which a plurality of display elements representing key types comprising letters, numerals, and symbols are formed.

3. A key sheet according to claim 2, wherein the soft-feel layer comprises through-holes as partition lines for partitioning the display elements.

4. A key sheet according to claim 2, wherein the soft-feel layer further comprises a porous layer on a back surface side of the character layer.

5. A key sheet according to claim 4, wherein the skin layer of the soft-feel layer comprises a protective portion for covering a side surface of an edge portion of the porous layer.

6. A key sheet according to claim 1, wherein:
the decorative portions of the soft-feel layer are provided on a back surface side of the skin layer and constitute display elements comprising letters, numerals, and symbols; and
the soft-feel layer further comprises a hair-implanted layer which is provided on the back surface side of the skin layer and in which piles are implanted in a direction crossing a plane direction of the base sheet.

7. A key sheet according to claim 6, wherein:
the hair-implanted layer comprises a support layer for bonding one ends of the piles; and
the piles are implanted in the support layer.

8. A key sheet according to claim 7, wherein all the base sheet, the skin layer, and the support layer are translucent.

9. A key sheet according to claim 6, wherein all the display elements are formed of a character layer comprising display portions and background portions formed by printing, the character layer being provided between the translucent skin layer and the translucent hair-implanted layer.

10. A key sheet according to claim 6, wherein the soft-feel layer comprises through-holes as partition lines for partitioning the display elements.

11. A key sheet according to claim 6, wherein:
the piles are made of a thermoplastic material; and
compressed portions formed by flattening the piles in a thickness direction of the hair-implanted layer are provided at edge portions of the hair-implanted layer.

12. A key sheet according to claim 6, wherein the skin layer is extended so as to form protective portions for covering side surfaces of edge portions of the hair-implanted layer.

13. A key sheet according to claim 1, wherein:
the skin layer of the soft-feel layer has a back surface formed in an asperity shape of an inclined surface;
each of the decorative portions of the soft-feel layer comprises
a first decorative layer formed on a back surface side of the skin layer and being non-uniform in layer thickness in recessed portions in the asperity shape, and
a second decorative layer formed on a back surface side of the first decorative layer and having a color different from that of the first decorative layer; and
an elastic layer is formed on a back surface side of the second decorative layer.

14. A key sheet according to claim 13, wherein a transparent and elastic medium layer for reducing a height difference in corrugation in the asperity shape is provided on the back surface of the skin layer.

15. A key sheet according to claim 13, wherein:
the first decorative layer comprises a display layer for displaying display elements comprising letters, numerals, and symbols; and
the soft-feel layer comprises through-holes as partition lines for partitioning the display elements.

16. A key sheet according to claim 13, wherein the second decorative layer comprises a metallic layer containing metal.

17. A key sheet according to claim 13, wherein:
the elastic layer comprises a porous layer; and
protective portions for covering side surfaces of edge portions of the porous layer are provided on the side surfaces thereof.

18. A key sheet according to claim 13, wherein:
the base sheet and the second decorative layer are translucent; and
an EL member is further provided on a back surface of the base sheet.

19. A key sheet according to claim 1, wherein:
the base sheet is translucent;
the soft-feel layer further comprises a porous layer laminated on a back surface side of the skin layer, the porous layer having a thickness ranging from 250 μm to 700 μm; and
each of the decorative portions of the soft-feel layer comprises
first decorative portions provided between the skin layer and the porous layer and being visible through the skin layer, and
second decorative portions provided on a back surface side of the porous layer and being visible with aid of light through the skin layer and the porous layer from the back surface side thereof.

20. A key sheet according to claim 19, wherein the porous layer comprises an open-cell foam layer in which foams are continuous with each other in a thickness direction.

21. A key sheet according to claim 20, wherein the porous layer has a thickness ranging from 250 μm to 450 μm.

22. A key sheet according to claim 19, wherein:
a back surface of the skin layer is formed as an asperity surface; and
a transparent and elastic medium layer for reducing a height difference in corrugation in the asperity surface is provided on the asperity surface.

23. A key sheet according to claim 19, wherein:
the first decorative portions comprise display portions for displaying display elements comprising letters, numerals, and symbols; and
the soft-feel layer comprises through-holes as partition lines for partitioning the display elements.

24. A key sheet according to claim 19, wherein protective portions for covering side surfaces of edge portions of the porous layer are provided on the side surfaces thereof.
